(19) United States
(12) Patent Application Publication
(10) Pub. No.: US 2018/0108309 A1
(43) Pub. Date: Apr. 19, 2018

(54) SHIFT REGISTER CIRCUIT, AND DISPLAY DEVICE INCLUDING SAME

(71) Applicant: Sharp Kabushiki Kaisha, Sakai City, Osaka (JP)

(72) Inventors: Kohhei TANAKA, Sakai City (JP); Takeshi NOMA, Sakai City (JP); Takayuki NISHIYAMA, Sakai City (JP); Ryo YONEBAYASHI, Sakai City (JP); Yasuyuki OGAWA, Sakai City (JP); Kaoru YAMAMOTO, Sakai City (JP)

(21) Appl. No.: 15/318,043

(22) PCT Filed: Jun. 9, 2015
(86) PCT No.: PCT/JP2015/066621

§ 371 Date: Feb. 10, 2017

(30) Foreign Application Priority Data
Jun. 13, 2014 (JP) 2014-122391

(51) Int. Cl. G09G 3/36; G11C 19/28

(52) U.S. Cl. CPC G09G 3/3648; G09G 2310/0286; G11C 19/28

(57) ABSTRACT

Each driving circuit in a shift register includes an output unit, a precharge unit, a boosting unit, a gate voltage discharge unit, a gate line discharge unit, and an internal line netA. The output unit includes a TFT(F) that outputs a selection voltage to a gate line. The precharge unit includes a TFT(B) that outputs a control voltage for causing the TFT in the output unit to operate. The boosting unit boosts up a gate voltage of the TFT in the output unit through a capacitor (Cbst). The gate voltage discharge unit includes a TFT(K) that pulls down this gate voltage during a non-selection period while the gate line is not selected. The gate line discharge unit includes a TFT(L) that outputs a non-selection voltage to the gate line during the non-selection period while the gate line is not selected. The internal line is connected to a gate terminal of the TFT in the output unit, the precharge unit, the gate voltage discharge unit, and the boosting unit. A gate terminal of at least one of the TFTs in the precharge unit, the gate voltage discharge unit, and the gate line discharge unit is connected to an internal line in another driving circuit.

### TECHNICAL FIELD

The present invention relates to a shift register circuit, and a display device including the same.

### BACKGROUND ART

A shift register circuit that sequentially scans a plurality of gate lines provided on an active matrix substrate has been known conventionally. The shift register circuit includes a driving circuit for every gate line, the driving circuit including an output transistor that switches the gate line into a selected state, a precharge transistor that precharges a gate voltage for the output transistor, and a bootstrap capacitor that boots up the precharge voltage. For the precharge transistor, a diode-connected transistor is used, and the precharge voltage has a voltage value that is decreased for the threshold voltage for the precharge transistor. If the precharge voltage decreases due to an increase of the threshold voltage caused when the transistor degrades, the gate voltage of the output transistor also decreases, which causes the operation of the driving circuit to become unstable. As a result, the operation margin of the shift register circuit decreases.

JP-T-2008-508654 discloses a shift register circuit that prevent a decrease in the gate voltage of the output transistor depending on the threshold voltage of the precharge transistor. The shift register circuit has such a configuration that, to the drain terminal of the precharge transistor, a row pulse of the previous stage is input, and to the gate terminal thereof, a precharge circuit for boosting up the gate voltage of the precharge transistor is connected. According to JP-T-2008-508654, even if the threshold voltage of the precharge transistor fluctuates, the precharge circuit boosts up the gate voltage of the precharge transistor, thereby preventing the decrease of the precharge voltage.

### SUMMARY OF THE INVENTION

The voltage reduction when the gate voltage of the output transistor is precharged can be prevented by providing a precharge circuit, as is the case with the configuration disclosed in JP-T-2008-508654, but the number of circuit elements of each driving circuit increases, which causes the circuit size of the shift register circuit to increase.

Further, in a case where the gate voltage of the output transistor and the discharge of the gate line are not enough when a gate line is put into the non-selected state, unintended entry of noises occurs to the gate lines, which makes it impossible to appropriately scan the gate lines. This causes the operation margin of the shift register circuit to decrease.

It is an object of the present invention to provide techniques for causing each driving circuit in a shift register circuit to stably operate, to improve the operation margin of the shift register circuit.

A shift register circuit according to the present invention is a shift register circuit that switches each of a plurality of gate lines provided on an active matrix substrate to a selected state or a non-selected state. The shift register circuit includes: a plurality of driving circuits that are connected to the respective gate lines and switch the gate lines to a selected state or a non-selected state, and each of the driving circuits includes: an output unit that includes a switching element that is connected to one of the gate lines, and outputs a selection voltage for switching the one gate line to a selected state; a precharge unit that includes a switching element that outputs a control voltage for causing the switching element in the output unit to operate; a boosting unit that includes a capacitor and a switching element that charges the capacitor, and boosts up a gate voltage of the switching element in the output unit through the capacitor; a gate voltage discharge unit that includes a switching element that pulls down the gate voltage during a non-selection period while the one gate line is switched to the non-selected state; a gate line discharge unit that includes a switching element that outputs a non-selection voltage to the one gate line during the non-selection period while the one gate line is not selected; and an internal line to which the gate terminal of the switching element in the output unit, the precharge unit, the gate voltage discharge unit, and the boosting unit are connected. A gate terminal of at least one switching element among the switching elements in the precharge unit, the gate voltage discharge unit, and the gate line discharge unit is connected to the internal line of another one of the driving circuits.

The configuration of the present invention allows each driving circuit of the shift register circuit to stably operate, thereby to improve the operation margin of the shift register circuit.

### BRIEF DESCRIPTION OF DRAWINGS

FIG. 1 is a schematic diagram illustrating a schematic configuration of a liquid crystal display device according to Embodiment 1.

FIG. 2 is a schematic diagram illustrating a schematic configuration of the active matrix substrate illustrated in FIG. 1.

FIG. 3 is a schematic diagram illustrating schematic configurations of the active matrix substrate illustrated in FIG. 1 and each part connected with the active matrix substrate.

FIG. 4 illustrates exemplary waveforms of clock signals in Embodiment 1.

FIG. 5 illustrates an exemplary equivalent circuit of the driving circuit illustrated in FIG. 3.

FIG. 6A is a schematic diagram illustrating an exemplary arrangement of elements of the driving circuit illustrated in FIG. 5.

FIG. 6B is a schematic diagram illustrating an exemplary arrangement of elements of the driving circuit illustrated in FIG. 5.

FIG. 6C is a schematic diagram illustrating an exemplary arrangement of elements of the driving circuit illustrated in FIG. 5.

FIG. 6D is a schematic diagram illustrating an exemplary arrangement of elements of the driving circuit illustrated in FIG. 5.

FIG. 7 is a timing chart when the driving circuit in Embodiment 1 drives gate lines.

FIG. 8 illustrates an exemplary equivalent circuit of a conventional driving circuit.

FIG. 9 explains changes in the potential of a netA of a conventional driving circuit, and that of the driving circuit in Embodiment 1.

FIG. 10 illustrates an exemplary equivalent circuit of a driving circuit in an application example of Embodiment 1.

FIG. 11 is a schematic diagram illustrating an exemplary arrangement of elements of the driving circuit illustrated in FIG. 10.

FIG. 12 is a timing chart when the driving circuit in an application example of Embodiment 1 drives gate lines.

FIG. 13 illustrates an equivalent circuit of a driving circuit in Embodiment 2.

FIG. 14A is a schematic diagram illustrating an exemplary arrangement of some of elements of the driving circuit illustrated in FIG. 13.

FIG. 14B is a schematic diagram illustrating an exemplary arrangement of some of elements of the driving circuit illustrated in FIG. 13.

FIG. 15 is a timing chart when the driving circuit in Embodiment 2 drives gate lines.

FIG. 16 illustrates an exemplary equivalent circuit of a driving circuit in Embodiment 3.

FIG. 17A is a schematic diagram illustrating an exemplary arrangement of some of elements of the driving circuit illustrated in FIG. 16.

FIG. 17B is a schematic diagram illustrating an exemplary arrangement of some of elements of the driving circuit illustrated in FIG. 16.

FIG. 18 is a timing chart when the driving circuit in Embodiment 3 drives gate lines.

FIG. 19 illustrates an exemplary equivalent circuit of a driving circuit in Embodiment 4.

FIG. 20A is a schematic diagram illustrating an exemplary arrangement of some of elements of the driving circuit illustrated in FIG. 19.

FIG. 20B is a schematic diagram illustrating an exemplary arrangement of some of elements of the driving circuit illustrated in FIG. 19.

FIG. 20C is a schematic diagram illustrating an exemplary arrangement of some of elements of the driving circuit illustrated in FIG. 19.

FIG. 20D is a schematic diagram illustrating an exemplary arrangement of some of elements of the driving circuit illustrated in FIG. 19.

FIG. 20E is a schematic diagram illustrating an exemplary arrangement of some of elements of the driving circuit illustrated in FIG. 19.

FIG. 20F is a schematic diagram illustrating an exemplary arrangement of some of elements of the driving circuit illustrated in FIG. 19.

FIG. 21 is a timing chart when the driving circuit in Embodiment 4 drives gate lines.

FIG. 22 illustrates an exemplary equivalent circuit of a driving circuit in Embodiment 5.

FIG. 23A is a schematic diagram illustrating an exemplary arrangement of some of elements of the driving circuit illustrated in FIG. 22.

FIG. 23B is a schematic diagram illustrating an exemplary arrangement of some of elements of the driving circuit illustrated in FIG. 22.

FIG. 23C is a schematic diagram illustrating an exemplary arrangement of some of elements of the driving circuit illustrated in FIG. 22.

FIG. 23D is a schematic diagram illustrating an exemplary arrangement of some of elements of the driving circuit illustrated in FIG. 22.

FIG. 24 is a timing chart when the driving circuit in Embodiment 5 drives some of gate lines.

FIG. 25 is a schematic diagram illustrating a schematic configuration of an active matrix substrate in Modification Example 1.

FIG. 26 illustrates exemplary waveforms of clock signals in Modification Example 1.

FIG. 27 illustrates an exemplary equivalent circuit of a driving circuit in in Modification Example 1.

FIG. 28A is a schematic diagram illustrating an exemplary arrangement of some of elements of the driving circuit illustrated in FIG. 27.

FIG. 28B is a schematic diagram illustrating an exemplary arrangement of some of elements of the driving circuit illustrated in FIG. 27.

FIG. 28C is a schematic diagram illustrating an exemplary arrangement of some of elements of the driving circuit illustrated in FIG. 27.

FIG. 28D is a schematic diagram illustrating an exemplary arrangement of some of elements of the driving circuit illustrated in FIG. 27.

FIG. 28E is a schematic diagram illustrating an exemplary arrangement of some of elements of the driving circuit illustrated in FIG. 27.

FIG. 29 is a timing chart when the driving circuit in Modification Example 1 drives gate lines.

FIG. 30 is a timing chart when the driving circuit in Modification Example 2 drives part of gate lines.

### MODES FOR CARRYING OUT THE INVENTION

A shift register circuit according to one embodiment of the present invention is a shift register circuit that switches each of a plurality of gate lines provided on an active matrix substrate to a selected state or a non-selected state. The shift register circuit includes: a plurality of driving circuits that are connected to the respective gate lines and switch the gate lines to a selected state or a non-selected state, and each of the driving circuits includes: an output unit that includes a switching element that is connected to one of the gate lines, and outputs a selection voltage for switching the one gate line to a selected state; a precharge unit that includes a switching element that outputs a control voltage for causing the switching element in the output unit to operate; a boosting unit that includes a capacitor and a switching element that charges the capacitor, and boosts up a gate voltage of the switching element in the output unit through the capacitor; a gate voltage discharge unit that includes a switching element that pulls down the gate voltage during a non-selection period while the one gate line is switched to the non-selected state; a gate line discharge unit that includes a switching element that outputs a non-selection voltage to the one gate line during the non-selection period while the one gate line is not selected; and an internal line to which the gate terminal of the switching element in the output unit, the precharge unit, the gate voltage discharge unit, and the boosting unit are connected. A gate terminal of at least one switching element among the switching elements in the precharge unit, the gate voltage discharge unit, and the gate line discharge unit is connected to the internal line of another one of the driving circuits (the first configuration).

In other words, the first configuration includes a plurality of driving circuits that are connected to the respective gate lines. Each of the driving circuits includes an output unit, a precharge unit, a boosting unit, a gate voltage discharge unit, a gate line discharge unit, and an internal line. The output unit includes a switching element that outputs a selection voltage to one of the gate lines. The precharge unit includes a switching element that outputs a control voltage for causing the switching element of the output unit to operate. The boosting unit includes a capacitor and a switching element that charges the capacitor, and boosts up a gate voltage of the switching element of the output unit through the capacitor. The gate voltage discharge unit includes a switching element that pulls down the gate voltage of the switching element of the output unit during a non-selection period while the one gate line is not selected. The gate line discharge unit includes a switching element that outputs a non-selection voltage to the one gate line during a non-selection period while the one gate line is not selected. The internal line is connected with a gate terminal of the switching element in the output unit, the precharge unit, and the boosting unit. A gate terminal of at least one switching element among the switching elements in the precharge unit, the gate voltage discharge unit, and the gate line discharge unit is connected to an internal line in another driving circuit.

According to the first configuration, the control voltage output from the precharge unit is input to the gate terminal of the switching element in the output unit through the internal line. Further, the boosting unit is connected to the internal line, so that the gate voltage of the switching element in the output unit is boosted up through the internal line. In other words, the potential of the internal line is boosted to a level equal to or higher than the level of the control voltage output from the precharge unit. At least one of the switching elements in the precharge unit, the gate voltage discharge unit, and the gate line discharge unit is turned ON according to the potential of the internal line in another driving circuit. Therefore, even if fluctuations of a threshold voltage occur due to deteriorations of the switching elements in the precharge unit, the gate voltage discharge unit, and the gate line discharge unit, at least one of the precharge unit, the gate voltage discharge unit, and the gate line discharge unit can be cause to stably operate. As a result, the application of the selection voltage to the gate line, the pulldown of the gate voltage during the non-selection period while the gate line is not selected, or the application of the non-selection voltage to the gate line can be performed surely, whereby the operation margin of the shift register circuit can be improved.

The configuration may be a second configuration such that, in the first configuration, a gate terminal of the switching element in the precharge unit is connected to the internal line in the another driving circuit, a source terminal thereof is connected to the internal line in the present driving circuit, and a drain terminal thereof is connected to another one of the gate lines.

According to the second configuration, the gate voltage can be charged to the potential of another gate line, without depending on the threshold voltage of the switching element in the precharge unit.

The configuration may be a third configuration such that, in the first configuration, a gate terminal of the switching element in the precharge unit is connected to the internal line in the another driving circuit, a source terminal thereof is connected to the internal line in the present driving circuit, and a drain terminal thereof is supplied with a control signal having a potential switched every predetermined period between a potential corresponding to the selected state and a potential corresponding to the non-selected state.

In a case where, as in the second configuration, the potential of the gate line is input to the drain terminal of the switching element in the precharge unit, when the output waveform of the gate line becomes dull, the charging capability of the precharge unit decreases in some cases, thereby becoming unable to charge the internal line sufficiently. According to the third configuration, a control signal having a potential switched every predetermined period between a potential corresponding to the gate line selected state and a potential corresponding to the non-selected state is input to the drain terminal of the switching element in the precharge unit. Therefore, as compared with the second configuration, the precharge unit can be caused to operate without depending on the output waveform of the gate line, which makes it possible to prevent the decrease of the charging capability due to the precharge unit.

The configuration may be a fourth configuration such that, in the first configuration, a gate terminal of the switching element in the gate voltage discharge unit is connected to the internal line in the another driving circuit, a source terminal thereof is connected to the internal line in the present driving circuit, and a drain terminal thereof is supplied with a control signal having a potential switched every predetermined period between a potential corresponding to the selected state and a potential corresponding to the non-selected state.

According to the fourth configuration, a control signal having a potential switched every predetermined period between a potential corresponding to the gate line selected state and a potential corresponding to the non-selected state is input to the drain terminal of the switching element in the gate voltage discharge unit. Therefore, the gate voltage can be pulled down at an appropriate timing during the non-selection period while the gate line is not selected.

The configuration may be a fifth configuration such that, in the first configuration, a gate terminal of the switching element in the gate line discharge unit is connected to the internal line in the another driving circuit, a source terminal thereof is connected to the internal line in the present driving circuit, and a drain terminal thereof is supplied with a control signal having a potential switched every predetermined period between a potential corresponding to the selected state and a potential corresponding to the non-selected state.

According to the fifth configuration, a control signal having a potential switched every predetermined period between a potential corresponding to the gate line selected state and a potential corresponding to the non-selected state is input to the source terminal of the switching element in the gate line discharge unit. Therefore, the gate line can be put into the non-selected state at an appropriate timing during the non-selection period while the gate line is not selected.

The configuration may be a sixth configuration such that, in any one of the first to fifth configurations, a source terminal of the switching element in the output unit is connected to the one gate line, and a drain terminal thereof is supplied with a direct current voltage signal having a potential corresponding to the selected state.

According to the sixth configuration, a direct current voltage signal having a potential corresponding to the gate line selected state is supplied to the drain terminal of the switching element in the output unit. Therefore, as compared with a case where a control signal having a potential repetitively switched every predetermined period between a potential corresponding to the selected state and a potential corresponding to the non-selected state is input, the loads and the electric power consumption for causing the output unit to operate can be reduced.

The configuration may be a seventh configuration such that, in any one of the first to fifth configurations, a source terminal of the switching element in the output unit is connected to the one gate line, and a drain terminal thereof is supplied with an instruction signal having a potential corresponding to either one of the selected state and the non-selected state.

According to the seventh configuration, an instruction signal having a potential corresponding to either one of the selected state and the non-selected state is input to the drain terminal of the switching element in the output unit, any gate lines can be switched to the selected state.

The configuration may be an eighth configuration such that, in any one of the first to seventh configurations, a plurality of source lines crossing each of the gate lines are provided on the active matrix substrate, and the driving circuits are provided in a display region defined by the gate lines and the source lines.

According to the eighth configuration, since the driving circuits are provided in the display region, the width of the frame region on the active matrix substrate can be reduced, as compared with a case where the driving circuit is provided outside the display region. Further, by providing the driving circuits in the display region, parasitic capacitances are generated in spaces between the driving circuits and the gate lines as well as the source lines, but since at least one of the switching elements in the precharge unit, the gate voltage discharge unit, and the gate line discharge unit is surely driven, the driving circuit can be caused to stably operate, whereby the operation margin of the shift register circuit can be improved.

A display device according to one embodiment of the present invention includes: an active matrix substrate including the shift register circuit in any one of the first to eighth configurations; a counter substrate including color filters; and a liquid crystal layer interposed between the active matrix substrate and the counter substrate (the ninth configuration).

The following describes embodiments of the present invention in detail, while referring to the drawings. Identical or equivalent parts in the drawings are denoted by the same reference numerals, and the descriptions of the same are not repeated.

### Embodiment 1

### (Exemplary Configuration of Active Matrix Substrate)

### Embodiment 1

### (Configuration of Liquid Crystal Display Device)

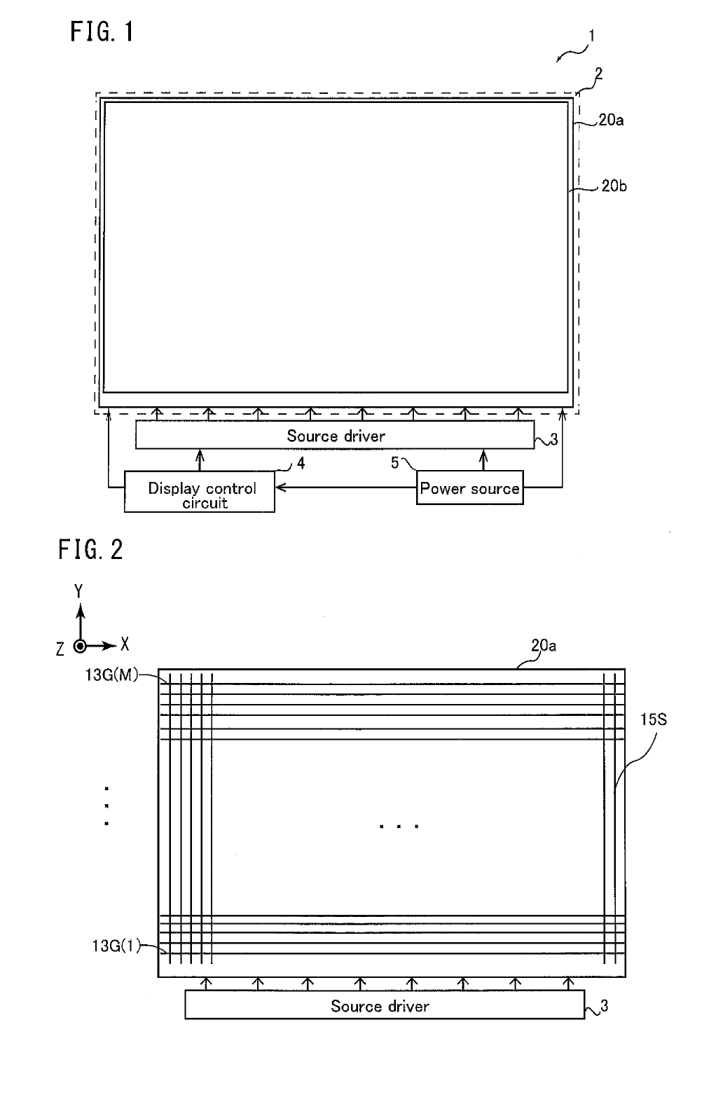

FIG. 1 is a schematic diagram illustrating a schematic configuration of a liquid crystal display device according to the present embodiment. The liquid crystal display device 1 includes a display panel 2, a source driver 3, a display control circuit 4, and a power source 5. The display panel 2 includes an active matrix substrate 20a, a counter substrate 20b, and a liquid crystal layer (not illustrated) interposed between these substrates. Though illustration is not shown in FIG. 1, a pair of polarizers sandwich the active-matrix substrate 20a and the counter substrate 20b A black matrix, and red (R), green (G), and blue (B) color filters, and a common electrode (all not illustrated) are formed on the counter substrate 20b.

As illustrated in FIG. 1, the active matrix substrate 20a is electrically connected with the source driver 3 formed in a flexible substrate. The display control circuit 4 is electrically connected with the display panel 2, the source driver 3, and the power source 5. The display control circuit 4 outputs control signals to the source driver 3 and shift register circuits (hereinafter referred to as gate drivers) described below, the shift register circuits being provided on the active matrix substrate 20a. The power source 5 is electrically connected with the display panel 2, the source driver 3, and the display control circuit 4, and supplies a power source voltage signal to each.

### (Structure of Active Matrix Substrate)

FIG. 2 is a schematic diagram illustrating a schematic configuration of the active matrix substrate 20a. On the active matrix substrate 20a, M (M: natural number) gate lines 13G(1) to 13G(M) are formed at predetermined intervals approximately in parallel from one end to the other end in the X-axis direction. Hereinafter, when the gate lines are collectively referred to as gate lines 13G when distinction is not made from one another. On the active matrix substrate 20a, a plurality of source lines 15S cross the gate lines 13G. Each area enclosed by the gate lines 13G and the source lines 15S forms one pixel, and each pixel corresponds to one of the colors of the color filters.

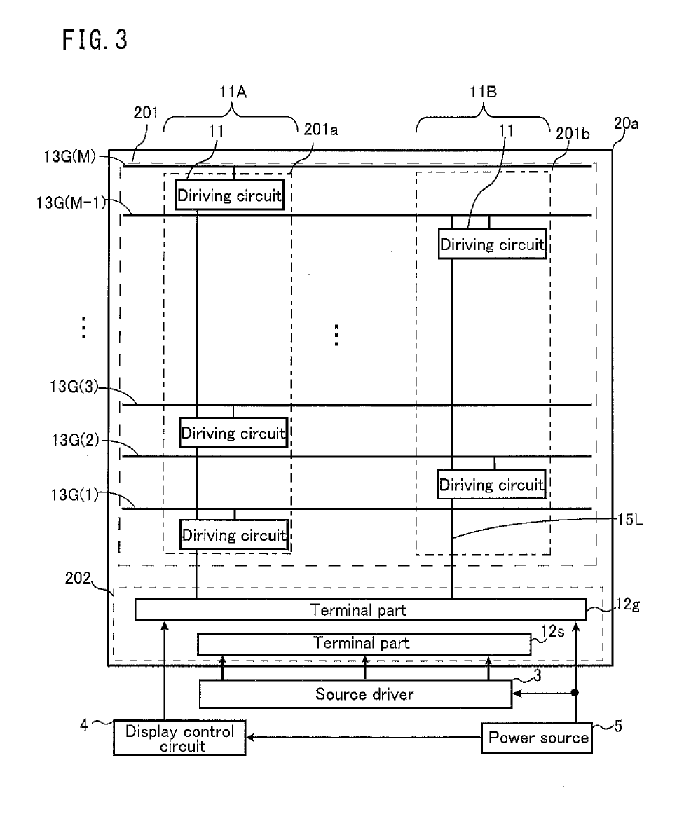

FIG. 3 is a schematic diagram illustrating schematic configurations of the active matrix substrate 20a illustrated in FIG. 1 and each part connected with the active matrix substrate 20a. In FIG. 3, for convenience sake, the illustration of the source lines 15S is omitted. As is the case with the example illustrated in FIG. 3, the gate drivers 11A, 11B are provided at each of the areas 201a and 201b of the display region 201 on the active matrix substrate 20a. The gate driver 11A is provided for the odd-numbered-row gate lines 13G, that is, the gate lines 13G(1), 13G(3), . . . and 13G(M), and includes a plurality of driving circuits 11 connected through the lines 15L. Further, the gate driver 11B is provided for even-numbered-row gate lines 13G, that is, the gate lines 13G(2), 13G(4), . . . and 13G(M−1), and includes a plurality of driving circuits 11 connected through the lines 15L.

On the active matrix substrate 20a illustrated in FIG. 3, in a frame region 202 on the side where the source driver 3 is provided, a terminal part 12g is provided. The terminal part 12g is connected with the display control circuit 4 and the power source 5. The terminal part 12g receives signals such as control signals and power source voltage signals from the display control circuit 4 and the power supply 5. Signals such as the control signals and the power source voltage signal input to the terminal part 12g are supplied through the lines 15L to each driving circuits 11. The driving circuit 11 outputs a voltage signal that indicates either a selected state or a non-selected state to the gate lines 13G connected therewith, according to the supplied signal. In the following description, the state in which the gate line 13G is selected is referred to as the driving of the gate line 13G.

Further, in the frame region 202 on the active matrix substrate 20a, a terminal part 12s is provided that connects the source driver 3 and the source line 15S (see FIG. 2) with each other. The source driver 3 outputs data signals to each source line 15S (see FIG. 2) according to control signals input from the display control circuit 4.

The display control circuit 4 supplies, as control signals, signals whose potentials are repetitively switched between an H level (VDD) and an L level (VSS) every two horizontal periods (hereinafter referred to as clock signals), and a signal having the same potential as the H-level potential of the clock signals (hereinafter referred to as a reset signal), to the terminal part 12g.

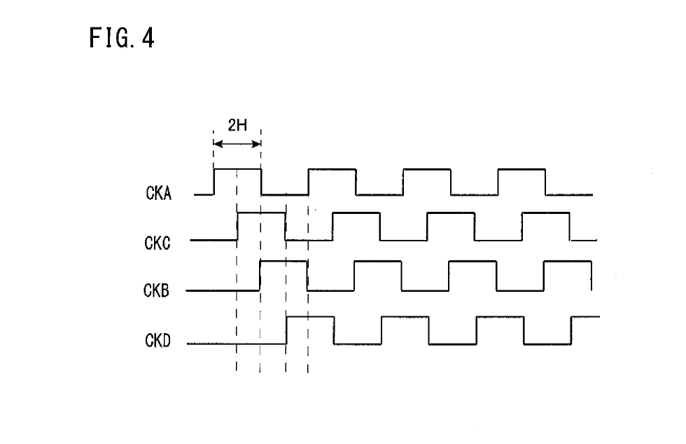

FIG. 4 illustrates exemplary waveforms of the clock signals. In the present embodiment, four-phase clock signals CKA, CKC, CKB, and CKD that have phases offset by ¼ cycle each are supplied as the clock signals to the terminal part 12g. The four-phase clock signals are used in this example, but alternatively, a plurality of clock signals having different phases, such as two-phase clock signals that are repetitively switched between the H level (VDD) and the L level (VSS) every one horizontal scanning period and that have phases offset by 1/2 cycle each, may be used.

### (Circuit Configuration)

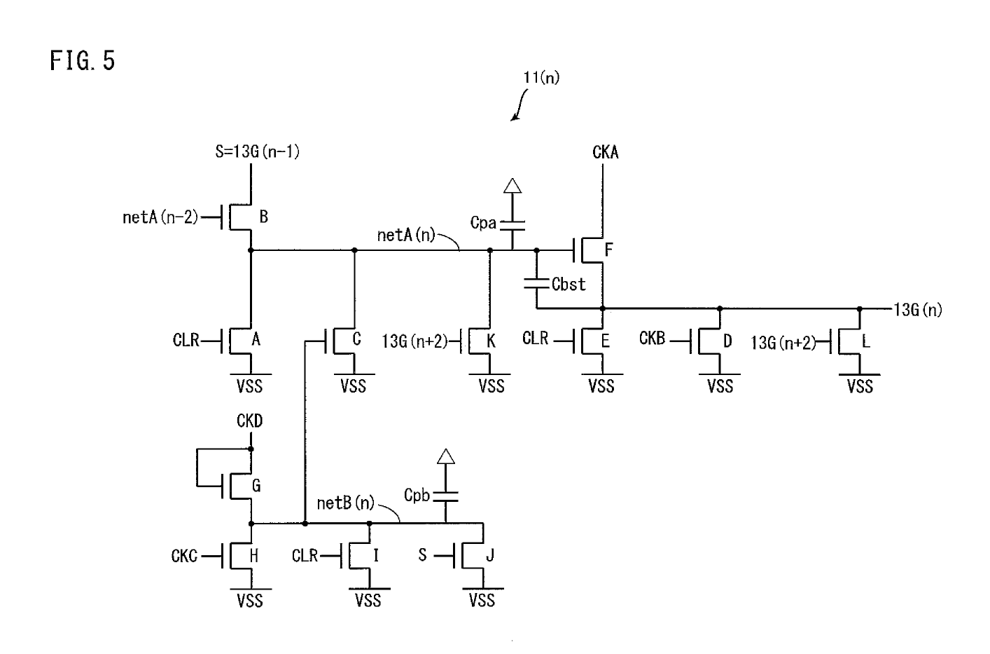

Next, the following describes the configuration of the driving circuit 11 in the present embodiment. FIG. 5 illustrates an exemplary equivalent circuit of a driving circuit 11 that drives the gate line 13G(n) (this driving circuit is hereinafter referred to as a driving circuit 11(n)).

As illustrated in FIG. 5, the driving circuit 11(n) includes, thin film transistors (TFTs) indicated by alphabetic characters A to L (hereinafter referred to as TFT-A to TFT-L), as switching elements,and a capacitor Cbst.

In FIG. 5, an internal line to which the source terminal of the TFT-B, the drain terminals of the TFT-A, the TFT-C, and the TFT-K, the gate terminal of the TFT-F, and one of the electrodes of the capacitor Cbst are connected is referred to as a netA. Further, an internal line to which the source terminal of the TFT-G, the drain terminals of the TFT-H, the TFT-I, and the TFT-J, and the gate terminal of the TFT-C are connected is referred to as a netB.

In the present embodiment, since the driving circuit 11 is provided in the display region, the netA and the netB have parasitic capacitances Cpa, Cpb, respectively, between the same and the source line 15S (see FIG. 2) or other elements provided in the pixels.

The drain terminal of the TFT-A is connected with the netA,the gate terminal of TFT-A is supplied with the reset signal CLR, and the source terminal is supplied with the power source voltage signal VSS. The TFT-A pulls down the potential of the netA(n) to the L level (VSS) according to the potential of the reset signal CLR.

To the gate terminal of the TFT-B, a netA (hereinafter referred to as a netA(n−2)) in a driving circuit 11 that drives the gate line 13G(n−2) (this driving circuit 11 is hereinafter referred to as a driving circuit 11(n−2)) is connected, the drain terminal of the TFT-B is connected with the gate line 13G(n−1), and the source terminal thereof is connected with a netA in the driving circuit 11(n) (this netA is hereinafter referred to as a netA(n)). The TFT-B receives a potential of the gate line 13G(n−1), as a set signal S. It should be noted that a TFT-B in a driving circuit 11 that drives a gate line 13G(1) receives a gate startpulse signal that is output from the display control circuit 4 as a set signal S.

In other words, in this example, to the gate terminal of the TFT-B in the driving circuit 11(n), a potential of the netA(n−2) in the driving circuit 11(n−2) provided for the gate line 13G(n−2) is supplied, the driving circuit 11(n−2) being driven two horizontal scanning periods before the timing for the driving of the gate line 13G(n). The TFT-B charges the netA(n) (precharges) by suppling the potential of the set signal S to the netA(n) according the potential of the netA(n−2).

Regarding the TFT-C, the gate terminal thereof is connected with the netB(n), the drain terminal thereof is connected with the netA(n), and the power source voltage signal VSS is supplied to the source terminal. The TFT-C pulls down the potential of the netA(n) to the L level (VSS) according to the potential of the netB(n).

Regarding the TFT-K, the gate terminal thereof is connected to the gate line 13G(n+2), the drain terminal thereof is connected to the netA(n), and to the source terminal thereof, the power source voltage signal VSS is supplied. The TFT-K pulls down the potential of the netA(n) to the L level (VSS) according to the potential of the gate line 13G(n+2).

Regarding the TFT-F, the gate terminal thereof is connected with the netA(n), the source terminal thereof is connected to the gate line 13G(n), and the drain terminal of the TFT-F is supplied with the clock signal CKA. The TFT-F supplies the potential of the clock signal CKA to the gate line 13G(n) according to the potential of the netA(n), thereby charging the capacitor Cbst, and switching the gate line 13G(n) into the selected state. The TFT-F drives the gate line having a relatively greater load, therefore the TFT-F needs to have a greater channel width than the other TFTs In the equivalent circuit illustrated in FIG. 5, the TFT-F is represented by one TFT, but the TFT-F is formed with a plurality of TFTs connected. A specific configuration example of the TFT-F is to be described below.

Regarding the capacitor Cbst, one of the electrodes thereof is connected with the netA(n), and the other electrode thereof is connected with the gate line 13G(n). The capacitor Cbst boosts up the potential of the netA(n) according to the potential of the clock signal CKA output from the TFT-F.

Regarding the TFT-E, the drain terminal thereof is connected with the gate line 13G(n), the gate terminal thereof is supplied with the reset signal CLR, and the source terminal thereof is supplied with the power source voltage signal VSS. The TFT-E pulls down the potential of the gate line 13G(n) to the L level (VSS) according to the potential of the reset signal CLR.

Regarding the TFT-D, the drain terminal thereof is connected with the gate line 13G(n), to the gate terminal thereof, the clock signal CKB is supplied, and the source terminal thereof is supplied with the power source voltage signal VSS. The TFT-D pulls down the potential of the gate line 13G(n) to the L level (VSS) according to the potential of the clock signal CKB.

Regarding the TFT-L, the drain terminal thereof is connected with the gate line 13G(n), the gate terminal thereof is connected with the gate line 13G(n+2), and the source terminal thereof is supplied with the power source voltage signal VSS. The TFT-L pulls down the potential of the gate line 13G(n) to the L level (VSS) according to the potential of the gate line 13G(n+2).

Regarding the TFT-G, the gate terminal thereof and the drain terminal thereof are connected, the gate terminal and the drain terminal thereof are supplied with the clock signal CKD, and the source terminal thereof is connected to the netB(n). The TFT-G supplies a potential of (the H-level potential of the clock signal CKD minus the threshold voltage) to the netB(n) according to the potential of the clock signal CKD.

Regarding the TFT-H, the drain terminal thereof is connected to the netB(n), the gate terminal thereof is supplied with the clock signal CKC, and the source terminal thereof is supplied with the power source voltage signal VSS. The TFT-H pulls down the potential of the netB(n) to the L level (VSS) according to the potential of the clock signal CKC.

Regarding the TFT-I, the drain terminal thereof is connected with the netB(n), the gate terminal thereof is supplied the reset signal CLR, and the source terminal thereof is supplied,with the power source voltage signal VSS. The TFT-I pulls down the potential of the netB(n) to the L level (VSS) according to the reset signal CLR.

Regarding the TFT-J, the drain terminal thereof is connected with the netB(n), the gate terminal thereof is connected with the gate line 13G(n−1), and the source terminal is supplied with the power source voltage signal VSS The TFT-J receives the potential of the gate line 13G(n−1) as the set signal S. The TFT-J in the driving circuit 11 that drives the gate line 13G(1) receives, as the set signal S, the gate startpulse signal output from the display control circuit 4. The TFT-J pulls down the potential of the netB(n) to the L level (VSS) according to the potential of the set signal S.

In other words, in the present embodiment, the TFT-F functions as an output unit that supplies a selection voltage corresponding to the selected state to the gate line 13G(n). The TFT-B functions as a precharge unit that supplies a control voltage to get the TFT-F to work to the netA(n), so as to charge the netA(n). The TFT-F and the capacitor Cbst function as a boosting unit that boosts up the potential of the netA(n) so as to boost up the gate voltage of the TFT-F. Further, the TFT-A, the TFT-K, and the TFT-C function as a gate voltage discharge unit that pulls down the potential of the netA(n). The TFT-E, the TFT-D, and the TFT-L function as a gate line discharge unit that outputs a non-selection voltage to the gate line 13G.

### (Exemplary Arrangement of the Driving Circuits)

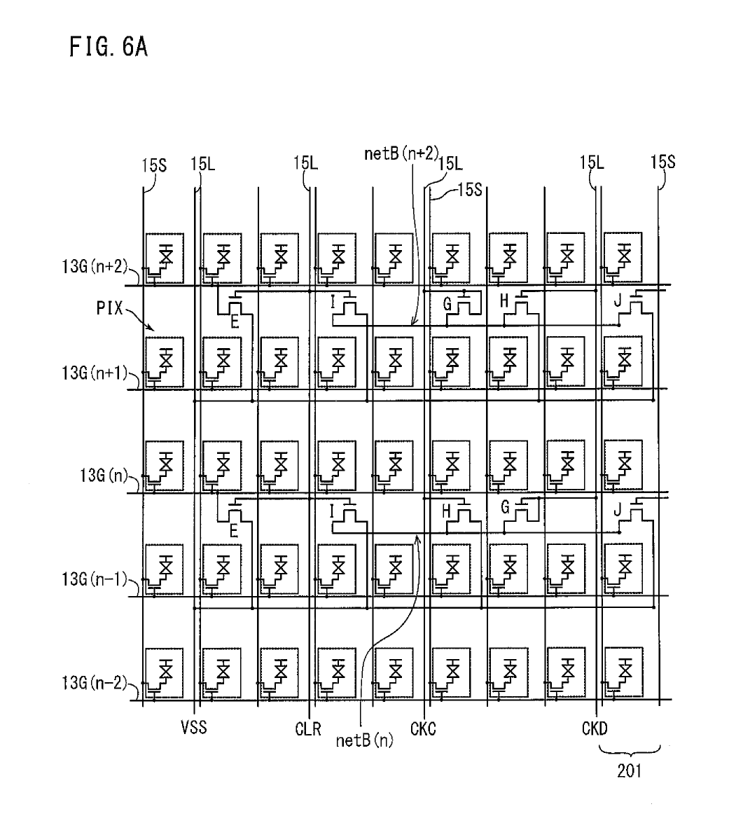

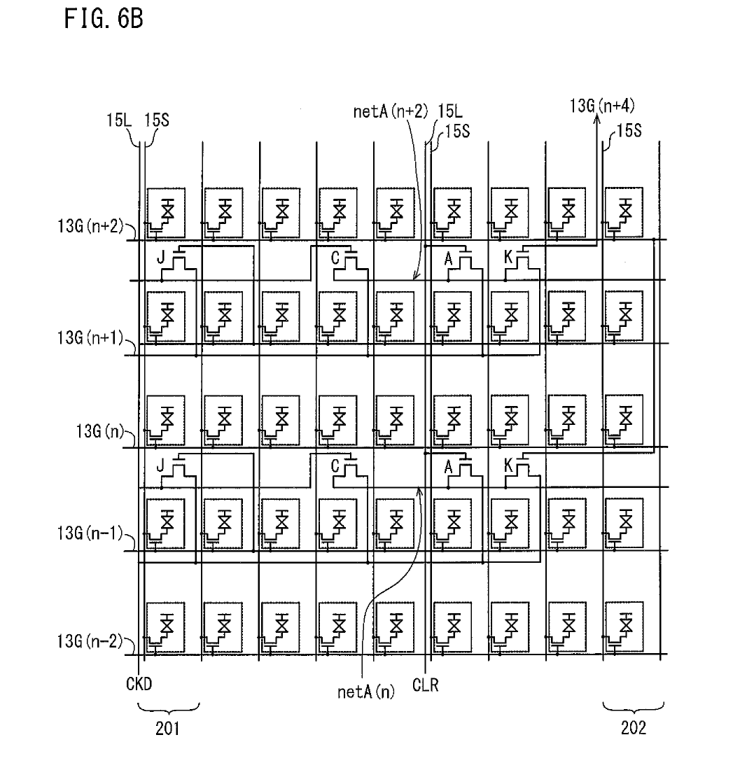

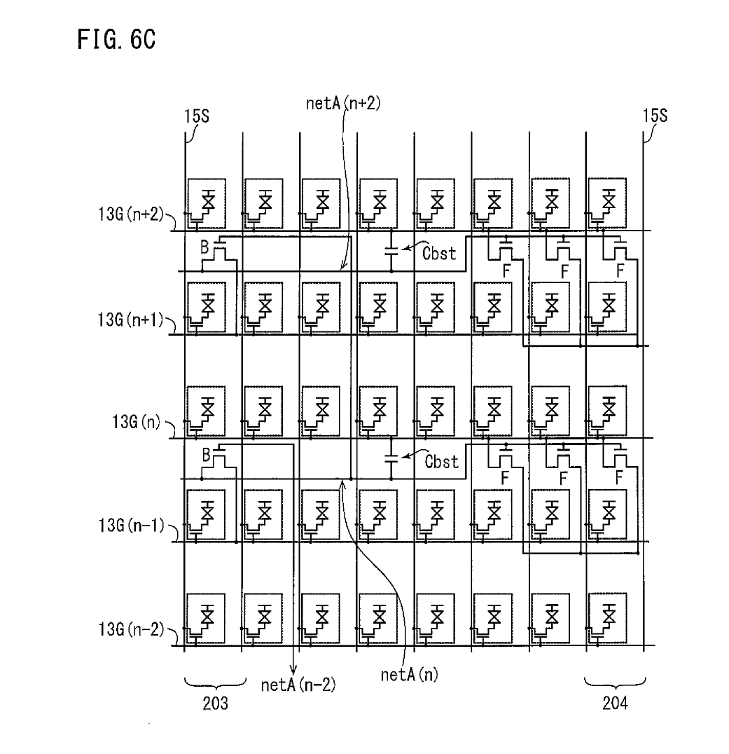

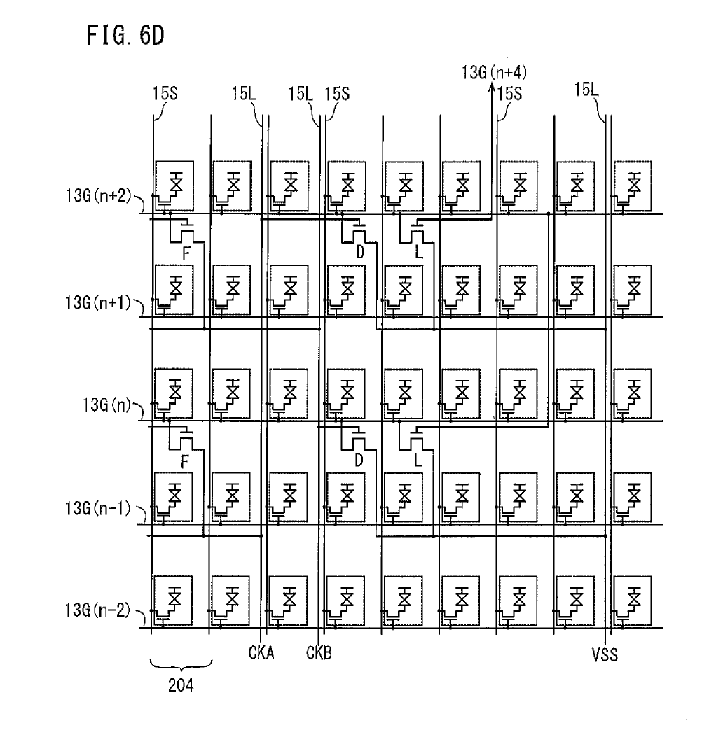

Next, the following describes an exemplary arrangement of the driving circuits 11 in the present embodiment. FIGS. 6A to 6D are schematic diagrams illustrating an exemplary arrangement of the driving circuit 11(n) and the driving circuit 11(n+2). In FIGS. 6A to 6D, for convenience sake, only the alphabetic characters A to L are illustrated, and the descriptions of “TFT-” are omitted; “A” to “L” correspond to the TFT-A to TFT-L illustrated in FIG. 5, respectively. Further, the respective display regions illustrated in FIG. 6A to 6D are continuous over the columns 201 to 204.

As illustrated in FIG. 6A to 6D, each element composing the driving circuit 11(n) is arranged in spaces between the gate lines among the gate lines 13G(n−2) to 13G(n). Further, each element composing the driving circuit 11(n+2) is arranged in spaces between the gate lines among the gate lines 13G(n) to 13G(n+2). The driving circuit 11(n) is connected with the gate line 13G(n−1), the gate line 13G(n), and the gate line 13G(n+2), and the driving circuit 11(n+2) is connected with the gate line 13G(n+1), the gate line 13G(n+2), and a gate line 13G(n+4) that is not illustrated.

As illustrated in FIGS. 6A, 6B, and 6D, the TFTs-E, the TFTs-I, the TFTs-H, the TFTs-G, the TFTs-J, the TFTs-C, the TFTs-A, the TFTs-K, the TFTs-D, and the TFTs-L of the driving circuit 11(n) and the driving circuit 11(n+2) are connected through the lines 15L that supply the power source voltage signal VSS. Further, as illustrated in FIG. 6A, the TFTs-H, and the TFTs-G of these driving circuits 11 are connected through the lines 15L that respectively supply the clock signals CKC, and CKD.

The lines 15L are provided approximately in parallel to the source lines 15S, in a source layer in which the source lines 15S are formed on the active matrix substrate 20a. Further, the lines of the netA in the driving circuits 11 are provided approximately in parallel to the gate lines 13G in a gate layer in which the gate lines 13G are formed.

As illustrated in FIGS. 6A and 6B, the lines 15L for supplying the power source voltage signal VSS are extended from the terminal part 12g (see FIG. 3) in rows other than the rows where the TFTs-E, the TFTs-I, the TFTs-H, the TFTs-G, the TFTs-J, the TFTs-C, the TFTs-A, and the TFTs-K are arranged, in such a manner that the lines 15L are approximately parallel to the source lines 15S, and are provided to pixels where the these TFTs are arranged. Further, in FIG. 6D also, the lines 15L for supplying the power source voltage signal VSS are laid from the terminal part 12g (see FIG. 3) in rows other than the rows where the TFTs-D and the TFTs-L are arranged, in such a manner that the lines 15L are approximately parallel to the source lines 15S, and are provided to pixels where these TFTs are provided.

Further, in FIG. 6A, the gate terminal of the TFT-H in the driving circuit 11(n) is connected to the line 15L for supplying the clock signal CKC, and the gate terminal of the TFT-H in the driving circuit 11(n+2) is connected to the line 15L for supplying the clock signal CKD. Still further, the gate terminal of the TFT-G in the driving circuit 11(n) is connected to the line 15L for supplying the clock signal CKD, and the gate terminal of the TFT-G in the driving circuit 11(n+2) is connected to the line 15L for supplying the clock signal CKC.

Further, as illustrated in FIG. 6C, the TFT-F is composed of three TFTs that are connected in parallel. The number of the connected TFTs is not limited to this, and one or more TFTs may be connected. Further, regarding the TFTs other than the TFT-F, and regarding the capacitor Cbst, the configuration may be such that a plurality of TFTs and a plurality of capacitors may be connected in parallel as required.

In FIG. 6C, each of the drain terminals of the three TFTs-F in the driving circuit 11(n) is connected to the line 15L to which the clock signal CKA is supplied. On the other hand, each of the drain terminals of the three TFTs in the driving circuit 11(n+2) is connected to the line 15L to which the clock signal CKB is supplied. Further, the lines 15L for supplying the clock signals CKA, CKB to each TFT-F are extended from the terminal part 12g (see FIG. 3) in rows other than the rows where the TFTs-F are arranged, in such a manner that the lines 15L are approximately parallel to the source lines 15S, and are provided to pixels where the these TFTs-F are provided.

In this way, to each driving circuit 11 in the gate drivers 11A, 11B, a clock signal having a phase opposite to that of the clock signal supplied to a driving circuit 11 adjacent to the gate driver concerned is supplied. Further, the clock signals supplied to the driving circuits 11 driving the adjacent gate lines 13G have phases offset by ¼ cycle from each other. For example, in a case where the clock signal CKA is input to the drain terminals of the TFTs-F in the driving circuit 11(n), the clock signal CKB is input to the drain terminals of the TFTs-F in the driving circuit 11(n−2) and the driving circuit 11(n+2). Further, the clock signal CKD is input to the drain terminals of the TFTs-F in the driving circuit 11(n−1), and the clock signal CKC is input to the drain terminals in the TFTs-F in the driving circuit 11(n+1).

### (Exemplary Operation of the Driving Circuit)

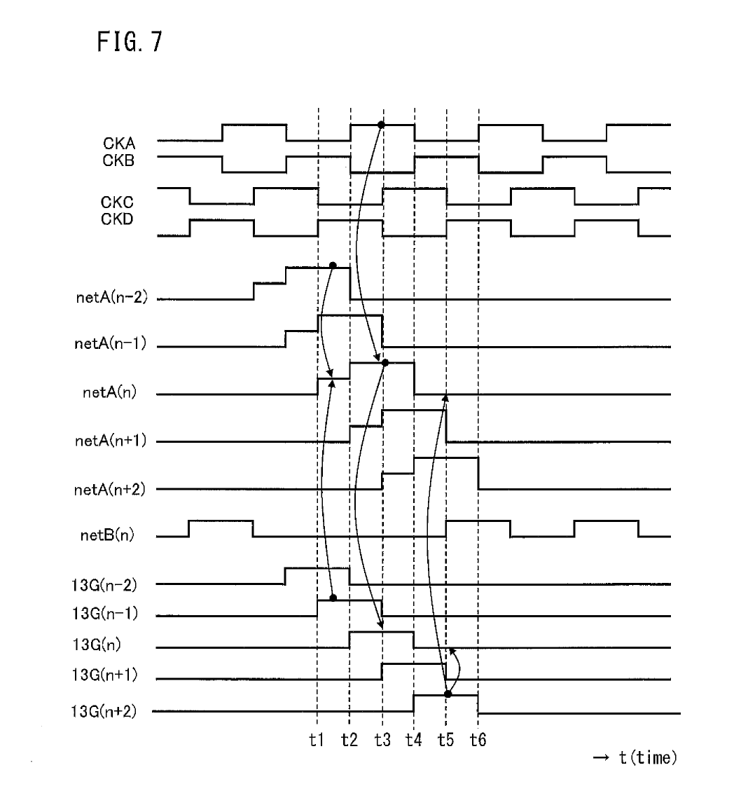

Next, the following describes operations of the driving circuit 11. FIG. 7 is a timing chart when the driving circuit 11(n) drives the gate line 13G(n).

The driving circuit 11(n) is supplied with the clock signals CKA, CKB, CKC, and CKD from the display control circuit 4. Though the illustration is omitted in FIG. 7, the reset signal CLR that goes to H (high) level at each vertical scan interval and remains that way for a predetermined period of time is supplied to each driving circuit 11 by the display control circuit 4. When the reset signal CLR is supplied, the potentials of the netA(n) and the netB(n) in the driving circuit 11(n), and the potential of the gate line 13G fall to a Low (L) level.

At the timing of a time t1, the gate line 13G(n−1) is switched to the selected state, and the H-level potential of the gate line 13G(n−1) is input, as the set signal S, to the drain terminal of the TFT-B in the driving circuit 11(n). The gate terminal of the TFT-B is supplied with the potential of the netA(n−2). The potential of the netA(n−2) has been at the H level since before the time t1, and the TFT-B is ON at the time t1. The TFT-B remains in the ON state until a time t2 when the potential of the netA(n−2) falls to the L level, whereby during the period from the time t1 to the time t2, the netA(n) is precharged so as to have the potential at the H level (VDD) of the of the gate line 13G(n−1).

The gate terminals of the TFTs-F is supplied with the H-level potential of the netA(n), whereby the TFT-F is turned ON. Since the H-level potential of the clock signal CKB is input to the gate terminal of the TFT-D at the time t1, the TFT-D is turned ON, and the potential at the L level (VSS) is supplied to the gate line 13G(n).

Further, at the time t1, the potential of the clock signal CKD is at the H level and the potential of the clock signal CKC is at the L level. As a result the TFT-G is turned ON, and the TFT-H is turned OFF. The gate terminal of the TFT-J is supplied with the H-level potential of the gate line 13G(n−1) as the set signal S, and the TFT-J is turned ON. The potential of the netB(n) is therefore maintained at the L level, and the TFT-C is turned OFF.

At the time t2, the potential of the clock signal CKA rises to the H level, and the H-level potential of the clock signal CKA is input through the TFTs-F to the gate line 13G(n). With the rise of the potential of the gate line 13G(n), the capacitor Cbst connected to between the netA(n) and the gate line 13G(n), the netA(n) is charged to have a potential higher than the H-level potential of the clock signal CKA. In other words, the netA(n) is charged to have a potential higher than the potential of (the precharge voltage VDD plus the threshold voltage Vth of the TFT-F).

At the time t2, the potential of the gate line 13G(n−1) is at the H level, and the TFT-J is maintained in the ON state. At a time t3, the potential of the clock signal CKC rises to the H level, and the TFT-H is turned ON. During a period from the time t2 to a t4, therefore, the potential of the netB(n) is maintained at the L level.

Further, at the time t2, the potential of the clock signal CKB falls from the H level to the L level, and the TFT-D is turned OFF. As a result, during a period from the time t2 to the time t4, the potential (selection voltage) at the H level of the clock signal CKA is supplied to the gate line 13G(n), and the gate line 13G(n) is switched to the selected state.

The driving circuit 11(n+1) that drives the gate line 13G(n+1) operates in the same manner as the driving circuit 11(n), using the potential of the gate line 13G(n) as the set signal S, so as to switch the gate line 13G(n+1) into the selected state at the timing of the time t3. Further, the driving circuit 11(n+2) that drives the gate line 13G(n+2) operates in the same manner as the driving circuit 11(n) using the potential of the gate line 13G(n+1) as the set signal S, whereby the gate line 13G(n+2) is switched to the selected state at the timing of the time t4.

At the time t4, the potential of the clock signal CKB rises to the H level, and the TFT-D is turned ON. Further, at the time t4, the potential of the gate line 13G(n+2) rises to the H level, and the TFT-K and the TFT-L are therefore turned ON. As a result a potential at the L level to be supplied through the TFT-D and the TFT-L to the gate line 13G(n), and the gate line 13G(n) is switched to a non-selected state. Further, through the TFT-K, a potential at the L level is input to the netA(n). Here, since the potential of the clock signal CKC is at the H level and the TFT-H remains in the ON state, the potential of the netB(n) is maintained at the L level.

Subsequently, at a time t5, when the potential of the clock signal CKD rises to the H level and the potential of the clock signal CKC falls to the L level, the TFT-H is turned OFF and the TFT-G is turned ON. As a result the netB(n) is charged so as to have a potential that is smaller by the threshold voltage of the TFT-G than the H-level potential of the clock signal CKD. Here, since the TFT-K and the TFT-L remain in the ON state and the TFT-C is turned ON, the potentials of the netA(n) and the gate line 13G(n) are maintained at the L level.

After a time t6, at a timing when the clock signal CKB comes to have a potential at the H level, the potential of the gate line 13G(n) is maintained at the L level, through the TFT-D.

Further, after the time t6, at a timing when the clock signal CKD comes to have a potential at the H level, the netB(n) is charged to have a potential at the H level, and the potential of the netA(n) is maintained at the L level, through the TFT-C.

In other words, the netB(n) is used for maintaining the potential of the netA(n) at the L level through the TFT-C. In a case where the gate line 13G(n) is switched to the selected state, however, the TFT-C needs to be in the OFF state. The TFT-C of the driving circuit 11(n) is turned ON according to the potential of the clock signal CKD during a non-selection period while the gate line 13G(n) is not selected. Further, the TFTs-F have a parasitic capacitance between the same and the line 15L that supplies the clock signal CKA. A noise in synchronization with the clock signal CKA enters the netA(n) due to the parasitic capacitance, while the potential of the netA(n) is maintained at the L level. In order to avoid this noise, the potential of the netB(n) transitions to the H level at the same timing as the clock signal CKD, so that the TFT-C is turned ON at a timing when the potential of the clock signal CKA transitions to the H level.

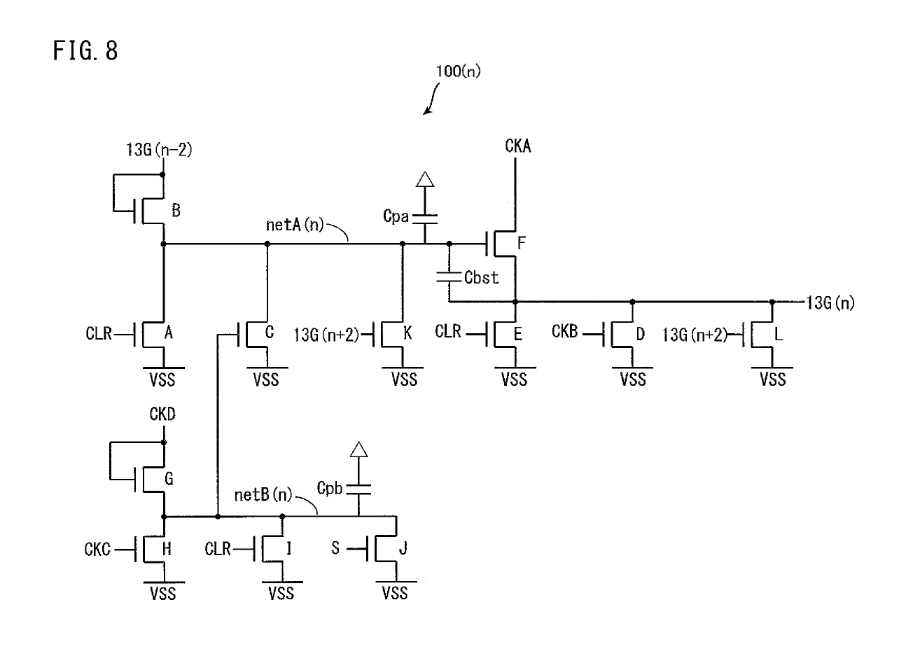

Here, an equivalent circuit of a conventional driving circuit 100(n) in which the diode-connected TFT-B is used is illustrated in FIG. 8. The driving circuit 100(n) illustrated in FIG. 8 has a configuration identical to the driving circuit 11(n) except that the potential of the gate line 13G(n−2) is supplied to the gate terminal and the drain terminal of the TFT-B.

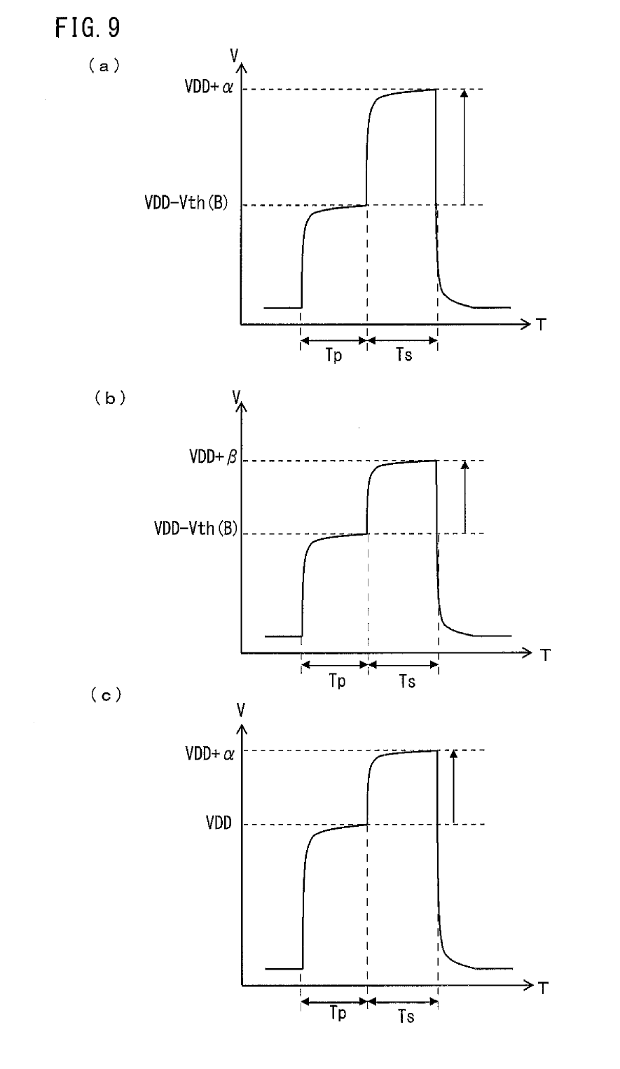

(a) of FIG. 9 illustrates a precharge period Tp while the netA(n) is precharged, and changes in the potential of the netA during a selection period Ts while the gate line 13G(n) is selected, in a case where the driving circuit 100(n)is arranged outside the display region. Further, (b) of FIG. 9 illustrates a precharge period Tp while the netA(n) is precharged, and changes in the potential of the netA(n) during a selection period Ts while the gate line 13G(n) is selected, in a case where the driving circuit 100(n) is arranged in the display region.

As illustrated in (a) of FIG. 9, in the driving circuit 100(n) provided outside the display region, during the precharge period Tp, a potential (VDD-Vth(B)), which is smaller by the threshold voltage (Vth(B)) of the TFT-B than the H-level potential (VDD) of the gate line 13G(n−2), is precharged in the netA(n). During the selection period Ts, the H-level potential of the clock signal CKA is supplied to the gate line 13G(n) through the TFTs-F, and the potential of the netA(n) is boosted up to a potential (VDD+α), which is higher than the precharge voltage, by the capacitor Cbst.

On the other hand, in a case where the driving circuit 100(n) is provided within the display region, the driving circuit 100(n) has a parasitic capacitance between the same and other elements provided in the display region such as the source lines 15S, and the parasitic capacitance of the netA(n) is greater than that in the case where the driving circuit 100(n) is provided outside the display region. As a result, the efficiency of the rise of the potential of the netA(n) through the capacitor Cbst decreases, which results in that, as illustrated in (b) of FIG. 9, the potential (VDD+β (β<α)) of the netA(n) during the selection period Ts is smaller than that in the case where the driving circuit 100(n) is arranged outside the display region. This causes the gate voltage of the TFTs-F to decrease, which makes it impossible to allow the driving circuit to stably operate, whereby the operation margin of the gate driver decreases.

In contrast, in Embodiment 1 described above, the potential of the netA(n−2) is supplied to the gate terminal of the TFT-B, and the potential of the gate line 13G(n−1) is supplied as a set signal to the drain terminal of the TFT-B. This results in that, as illustrated in (c) of FIG. 9, the precharge voltage of the netA(n) during the precharge period Tp, without decrease by the threshold voltage of the TFT-B, becomes the H-level potential (VDD) of the gate line 13G(n). This makes the following possible: even if the efficiency of the rise of the potential of the netA(n) decreases due to influences of a parasitic capacitance of the netA(n) in the driving circuit 11(n) provided in the display region, the potential of the netA(n) during the selection period Ts can be pulled up to the level equal to or higher than that in (a) of FIG. 9, which allows the driving circuit to stably operate, whereby the operation margin of the gate driver can be improved.

### <Application of Embodiment 1>

In the foregoing description of Embodiment 1, an example is described in which the potential of the gate line 13G(n−1) is supplied, as a set signal S input to the TFT-B in the driving circuit 11(n). The present application example is described with reference to an example in which a clock signal is input as a set signal S input to the TFT-B. In the following description, a configuration different from that of Embodiment 1 is described.

### (Circuit Configuration)

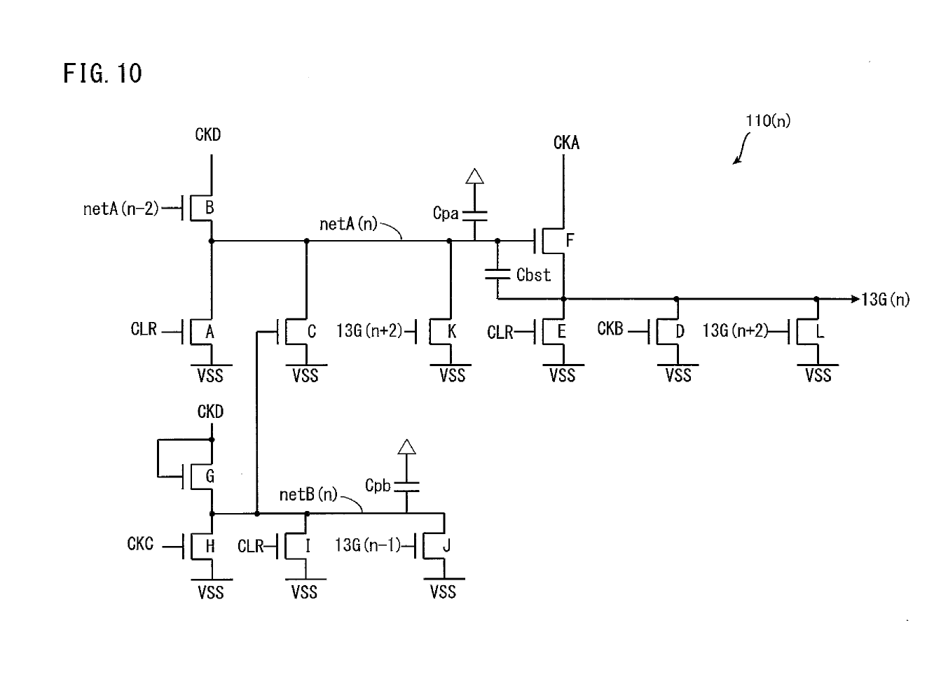

FIG. 10 illustrates an exemplary equivalent circuit of a driving circuit 110 in the present application example. As illustrated in FIG. 10, a driving circuit 110(n) that drives the gate line 13G(n) has the same configuration as that of the driving circuit 11(n) except that the clock signal CKD is input to the drain terminal of the TFT-B.

### (Exemplary Arrangement)

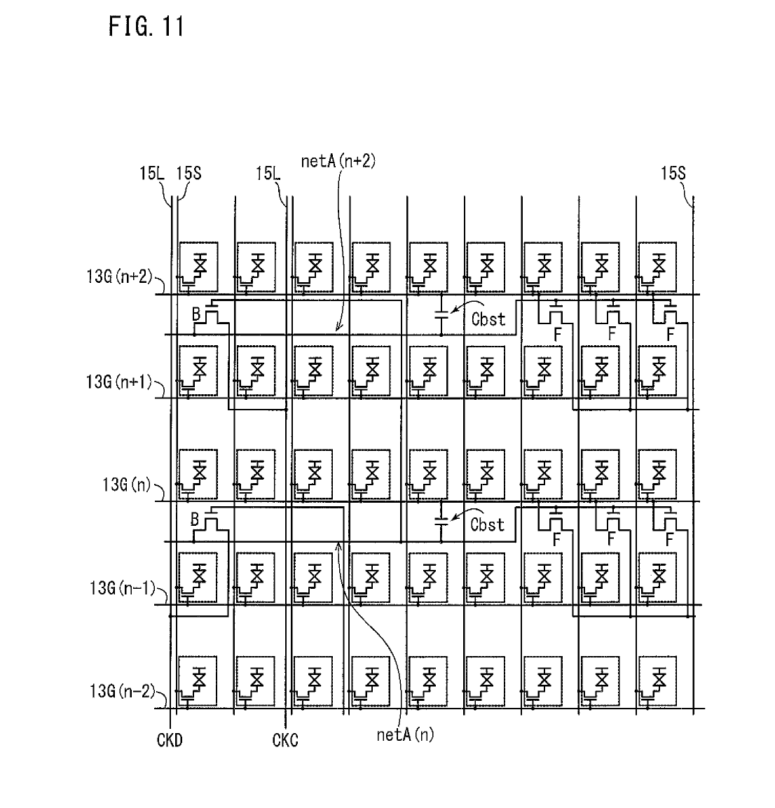

FIG. 11 is a schematic diagram illustrating an exemplary connection between a TFT-B of a driving circuit 110(n) and a TFT-B of a driving circuit 110(n+2) that drives a gate line 13G(n+2) in the display region. In FIG. 11, for convenience sake, the descriptions of “TFT-” are omitted, but the TFTs indicated by alphabetic characters in FIG. 11 correspond to the TFTs indicated by the same alphabetic characters in FIG. 10, respectively. As illustrated in FIG. 11, the drain terminal of the TFT-B in the driving circuit 110(n) is connected to the line 15L to which the clock signal CKD is supplied. Further, the drain terminal of the TFT-B in the driving circuit 110(n+2) is connected to the line 15L to which a clock signal CKD having a phase opposite to the phase of the foregoing clock signal CKC is supplied.

### (Exemplary Operation)

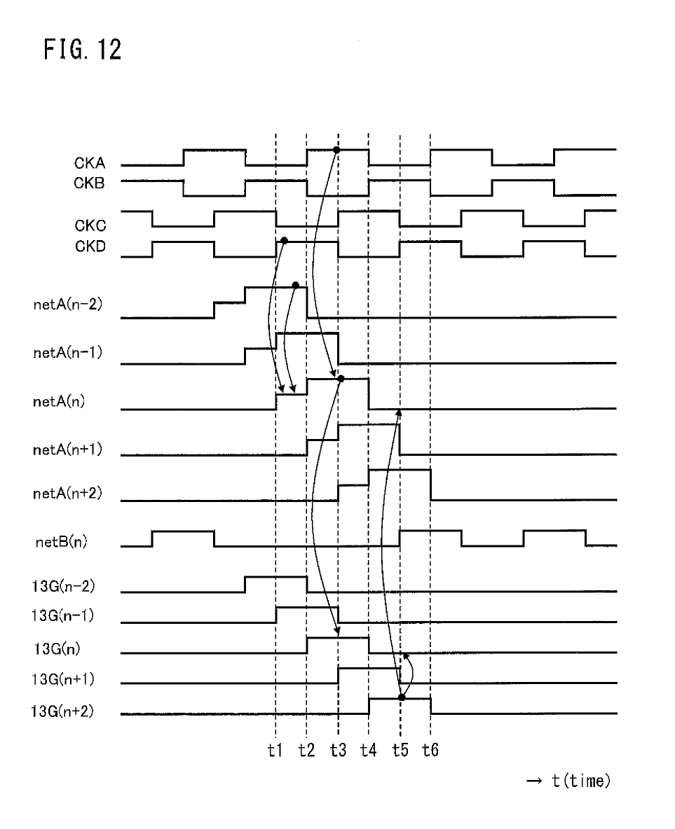

FIG. 12 is a timing chart when the driving circuit 110(n) drives the gate line 13G(n). The following description describes operations different from that in Embodiment 1.

At a time t1, the potential of the clock signal CKD rises to the H level, and here, since the TFT-B is ON, the potential at the H level (VDD) of the clock signal CKD is precharged in the netA(n) through the TFT-B. Since the clock signal CKD trasitions to the H level every two horizontal scanning periods, but the TFT-B is in an OFF state during periods other than the period while the potential of the netA(n−2) is at the H level. After the time t2, therefore, the H-level potential of the clock signal CKD is not supplied to the netA(n) through the TFT-B.

The gate line 13G has a relatively large parasitic capacitance, and the output waveform of the gate line 13G tends to be dull. Therefore, if the potential of the gate line 13G(n−1) is supplied to the drain terminal of the TFT-B as is the case with Embodiment 1, the dullness of the output waveform of the gate line 13G(n−1) influences, and thereby reduces the capability of precharging the netA(n) through the TFT-B. Further, along with the degradation of each TFT in the driving circuit 110, the dullness of the output waveform of the gate line 13G gradually increases. As a result, the capability of precharging the netA(n) further decreases, which causes the operation of the driving circuit to become unstable. In the application example of Embodiment 1, since the clock signals are input to the drain terminal of the TFT-B, the netA can be appropriately precharged, irrespective of the degree of the dullness of the output waveform of the gate line 13G.

### Embodiment 2

In the foregoing descriptions of Embodiment 1 and the application example of the same, examples are described in which a decrease in the precharge voltage of the netA is prevented so that the operation margin of the gate driver is improved. One of factors for the decrease in the operation margin of the gate driver is unsatisfactory pulldown of the potential of the netA when the gate line is switched into a non-selection state. Particularly, in a case where the gate driver is arranged in the display region, the potential of the netA cannot be pulled down surely to the L level in some cases, due to influences of parasitic capacitances generated between the gate driver and the elements provided in the display region such as the source lines 15S and the lines 15L. In the description of the present embodiment, an example is described in which, in order to improve the operation margin of the gate driver, the potential of the netA is more surely pulled down when the gate line is put into the non-selected state. The following describes only configurations different from those in Embodiment 1.

### (Circuit Configuration)

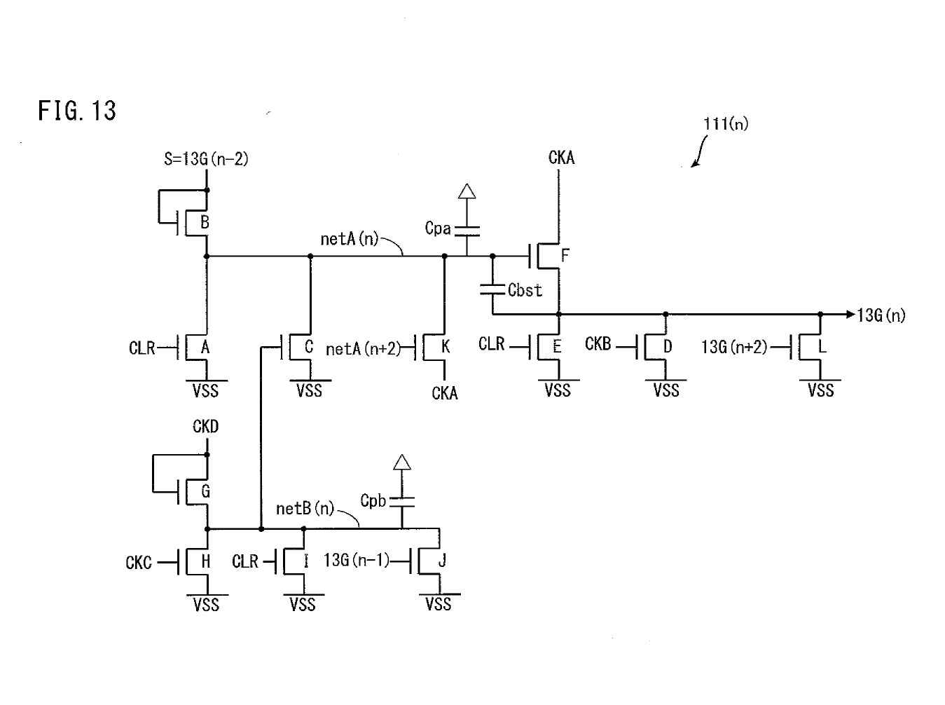

FIG. 13 an equivalent circuit of a driving circuit 111 in the present embodiment. As illustrated in FIG. 13, regarding the driving circuit 111(n) that drives the gate line 13G(n), the TFT-B for precharging the netA(n) is diode-connected. To the gate terminal and the drain terminal of the TFT-B, the potential of the gate line 13G(n−2) is supplied. Further, to the gate terminal of the TFT-K, the potential of the netA(n+2) in the driving circuit 111(n+2) that drives the gate line 13G(n+2) is supplied, and to the drain terminal of the TFT-K, the potential of the clock signal CKA is supplied.

### (Exemplary Arrangement)

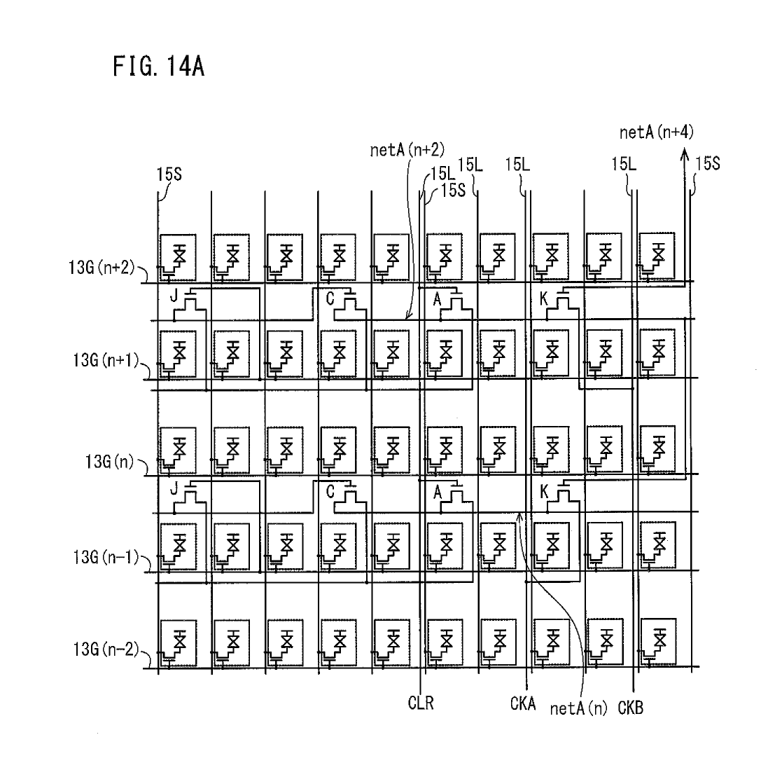

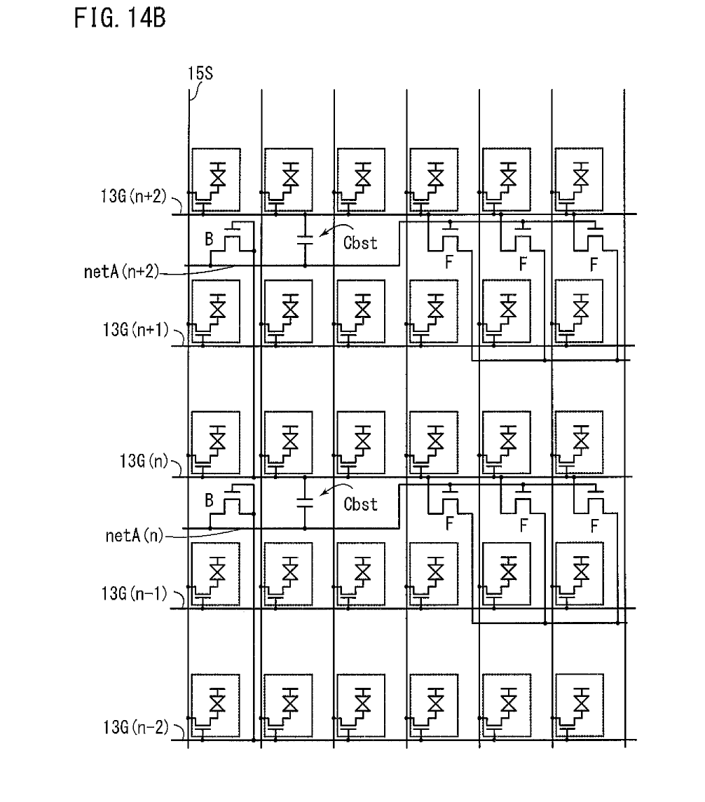

FIGS. 14A and 14B are schematic diagrams that illustrate an exemplary connection of the TFTs-K and the TFTs-B of the driving circuit 111(n) and the driving circuit 111(n+2) in the display region. In FIGS. 14A and 14B, for convenience sake, the descriptions of “TFT-” are omitted, but the TFTs indicated by alphabetic characters in FIGS. 14A and 14B correspond to the TFTs indicated by the same alphabetic characters in FIG. 13, respectively.

As illustrated in FIG. 14A, the gate terminal of the TFT-K in the driving circuit 111(n) is connected to the netA(n+2), and the gate terminal of the TFT-K in the driving circuit 111(n+2) is connected to the netA(n+4). The drain terminal of the TFT-K in the driving circuit 111(n) is connected to the line 15L that supplies the clock signal CKA, and the drain terminal of the TFT-K in the driving circuit 111(n+2) is connected to the line 15L that supplies the clock signal CKB.

Further, as illustrated in FIG. 14B, the gate terminal and the drain terminal of the TFT-B in the driving circuit 111(n) are connected to the gate line 13G(n−2), and the gate terminal and the drain terminal of the TFT-B in the driving circuit 111(n+2) are connected to the gate line 13G(n).

### (Exemplary Operation)

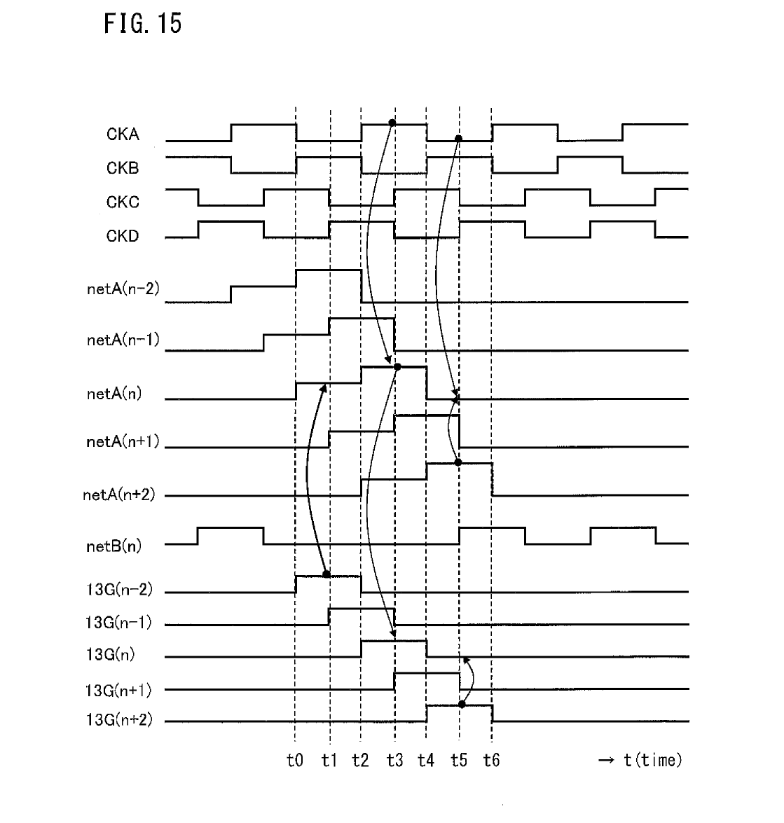

FIG. 15 is a timing chart when the driving circuit 111(n) drives the gate line 13G(n). The following describes operations different from those in Embodiment 1.

From a time t0 to a time t2 illustrated in FIG. 15, the gate line 13G(n−2) transitions to the selected state, and the H-level potential of the gate line 13G(n−2) is supplied to the gate terminal and the drain terminal of the TFT-B in the driving circuit 111(n). This causes the TFT-B to be turned ON, a potential smaller by the threshold voltage of the TFT-B than the H-level potential of the gate line 13G(n−2) is precharged to the netA(n) through the TFT-B.

From the time t2 to a time t4 illustrated in in FIG. 15, the H-level potential of the clock signal CKA is supplied to the gate line 13G(n) through the TFTs-F. The potential of the netA(n) is boosted up to a potential higher than the H level of the clock signal CKA through the capacitor Cbst, this potential of the netA(n) is supplied to the gate terminals of the TFTs-F, and the H-level potential of the clock signal CKA is supplied to the gate line 13G(n), whereby the gate line 13(n) trasitions to the selected state.

The TFT-J in the driving circuit 111(n) is in an ON state during a period from a time t1 to a time t3 while the potential of the gate line 13G(n−1) is at the H level, and the TFT-H therein is in an ON state during a period from the time t3 to a time t5 while the potential of the clock signal CKC is at the H level. This causes the potential of the netB(n) to be maintained at the L level from the time t1 to the time t5.

As illustrated in FIG. 15, the precharge of the netA(n+1) is started at the time t1, and the gate line 13G(n+1) is switched to the selected state at the time t3. Further, the precharge of the netA(n+2) is started at the time t2, and the gate line 13G(n+2) is switched to the selected state at the time t4.

At the time t4, the potential of the netA(n+2) rises to the H level, which causes the TFT-K to be turned ON. Here, since the clock signal CKA has a potential at the L level, the potential of the netA(n) is pulled down from the H level (VDD) to the L level (VSS), through the TFT-K. Further, the gate terminal of the TFT-L is supplied with the H-level potential of the gate line 13G(n+2) , which causes the TFT-L to be turned ON, whereby the potential of the gate line 13G(n) falls from the H level (VDD) to the L level (VSS).

After a time t6, since the potential of the netA(n+2) is at the L level, the TFT-K is turned OFF, but at a timing when the potential of the clock signal CKD rises to the H level, the potential of the netB(n) rises to the H level, and the potential of the netA(n) is maintained at the L level, through the TFT-C.

In Embodiment 2 described above, the netA(n+2) is connected to the gate terminal of the TFT-K that pulls down the potential of the netA(n) to the L level. The potential of the netA in the driving circuit 111 is boosted up to a level higher than the selection voltage, through the capacitor Cbst, during a selection period while the gate line 13G is selected. This causes the gate voltage of the TFT-K to increase, thereby increasing the value of the current flowing from the drain terminal of the TFT-K to the source terminal thereof, which causes the driving power of the TFT-K to increase. As a result, by arranging the driving circuit 111 in the display region, even if a parasitic capacitance Cpa is generated in the netA, the potential of the netA can be pulled down sufficiently through the TFT-K upon a transition during the non-selection period while the gate line 13G is not selected, whereby the driving circuit 111 can be caused to stably operate.

### Embodiment 3

In the foregoing description of Embodiment 2, an example is described in which, in order to improve the operation margin of the gate driver, to the gate terminal of the TFT-K that functions as a gate voltage discharge unit, a netA of another driving circuit is connected, so that the driving power of the TFT-K is improved. In the present embodiment, the discharge of a gate line upon a transition during the non-selection period while the gate line is not selected is enhanced, so that the operation margin of the gate driver is improved. Hereinafter, configurations different from those in Embodiment 2 are described.

### (Circuit Configuration)

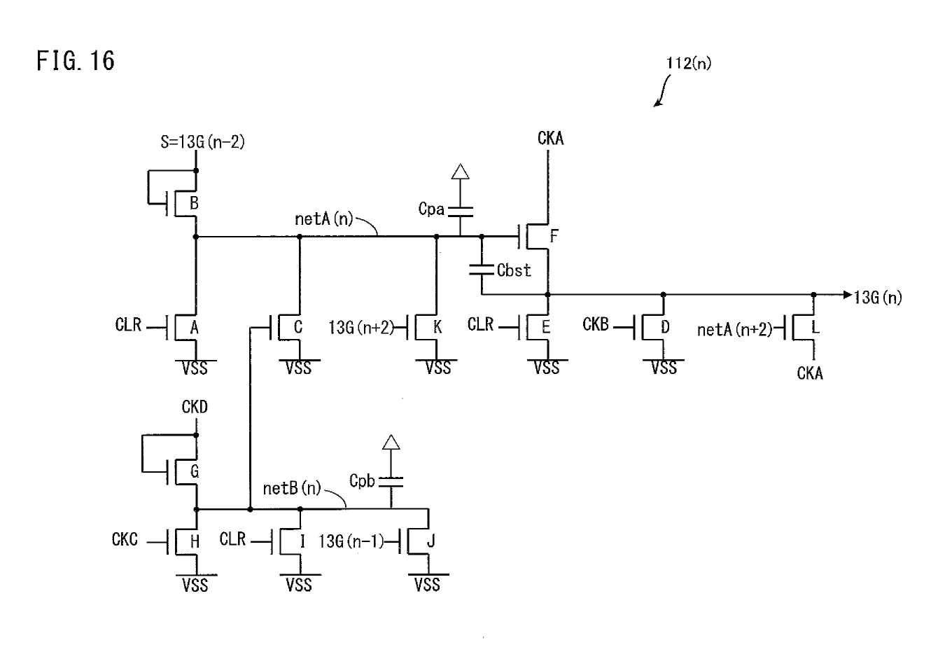

FIG. 16 illustrates an exemplary equivalent circuit of a driving circuit 112 in the present embodiment. As illustrated in FIG. 16, in the driving circuit 112(n) that drives the gate line 13G(n), regarding the TFT-K for pulling down the potential of the netA(n), the gate line 13G(n+2) is connected to the gate terminal thereof, the netA(n) is connected to the drain terminal thereof, and the power source voltage signal VSS is input to the source terminal thereof. Further, regarding the TFT-L that outputs a non-selection voltage to the gate line 13G(n), the netA(n+2) in the driving circuit 112(n+2) is connected to the gate terminal thereof, the clock signal CKA is supplied to the drain terminal thereof, and the gate line 13G(n) is connected to the source terminal thereof.

### (Exemplary Arrangement)

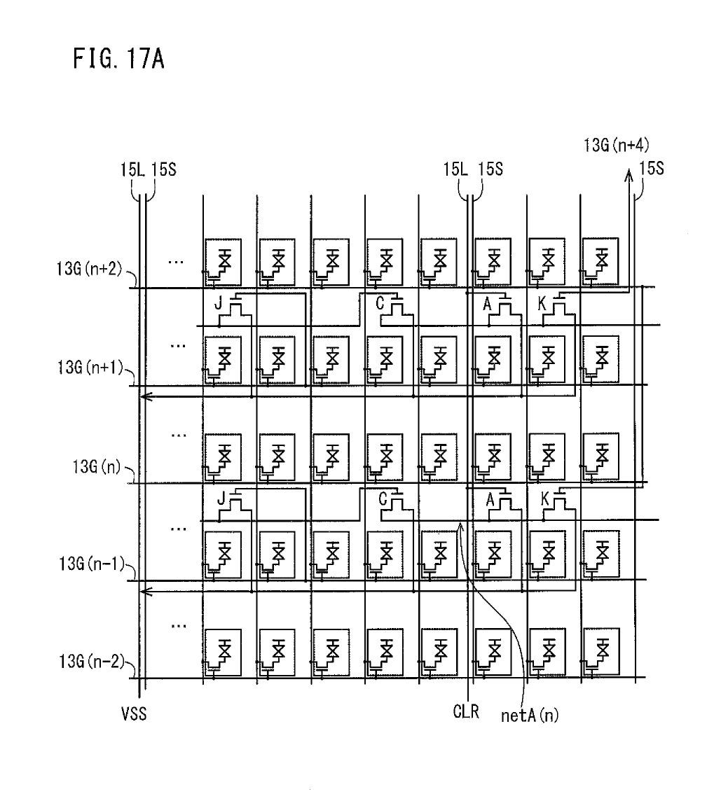

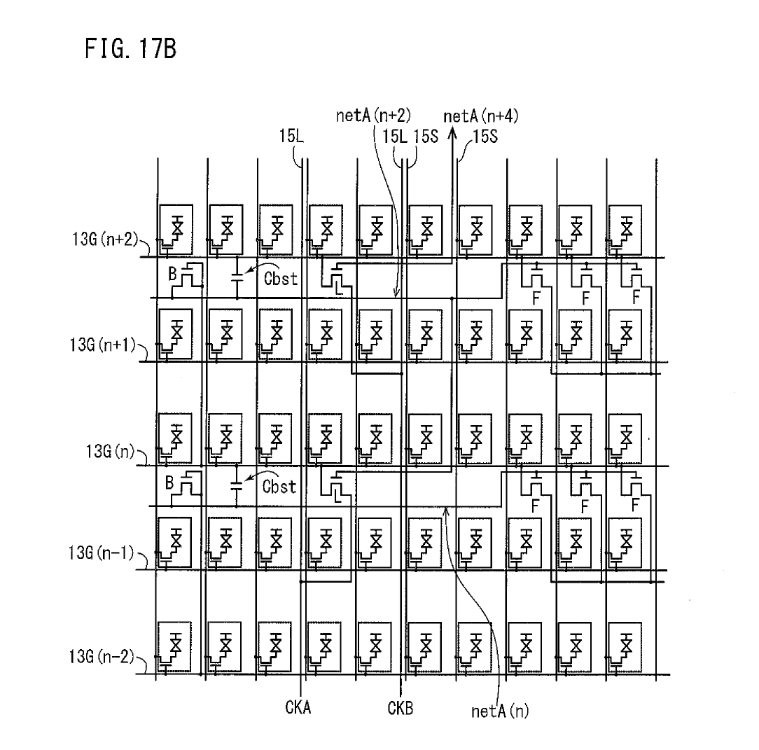

FIGS. 17A and 17B schematically illustrate exemplary connection of the TFTs-K and the TFTs-L of the driving circuit 112(n) and the driving circuit 112(n+2) in the display region. In FIGS. 17A and 17B, for convenience sake, the description of “TFT-” is omitted, but the TFTs indicated by alphabetic characters in FIGS. 17A and 17B correspond to the TFTs indicated by the same alphabetic characters in FIG. 16, respectively.

As illustrated in FIG. 17A, the gate terminal of the TFT-K in the driving circuit 112(n) is connected to the gate line 13G(n+2), and the gate terminal of the TFT-K in the driving circuit 112(n+2) is connected to the gate line 13G(n+4). The source terminals of the TFTs-K in the driving circuit 112(n) and the driving circuit 112(n+2) are connected to the line 15L that supplies the power source voltage signal VSS.

Further, as illustrated in FIG. 17B, the gate terminal of the TFT-L in the driving circuit 112(n) is connected to the netA(n+2), and the drain terminal thereof is connected to the line 15L that supplies the clock signal CKA. The gate terminal of the TFT-L in the driving circuit 112(n+2) is connected to the netA(n+4), and the drain terminal thereof is connected to the line 15L that supplies the clock signal CKB.

### (Exemplary Operation)

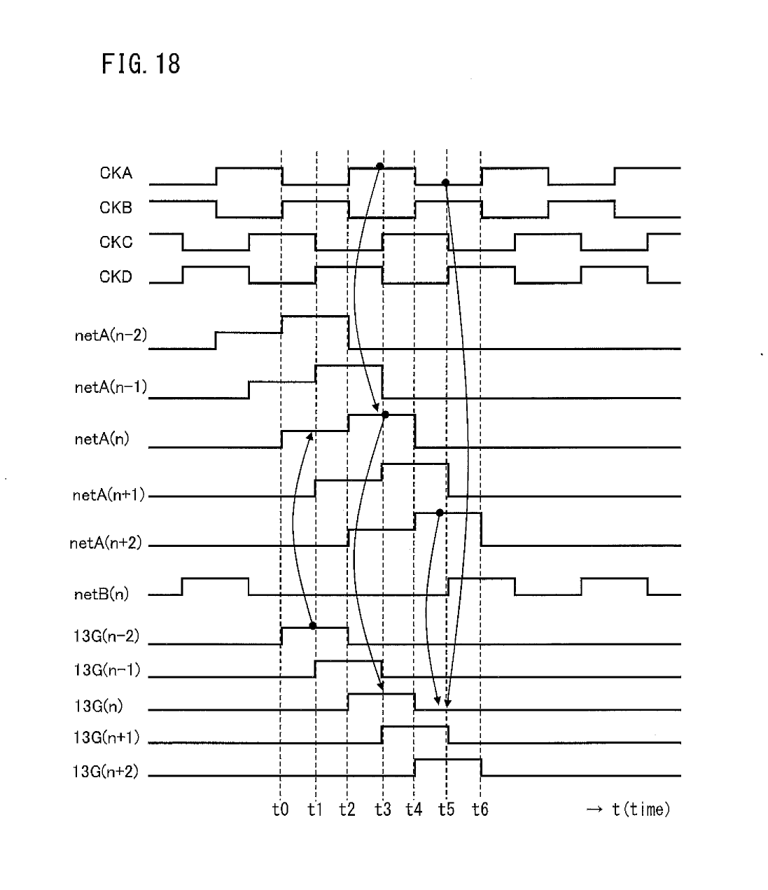

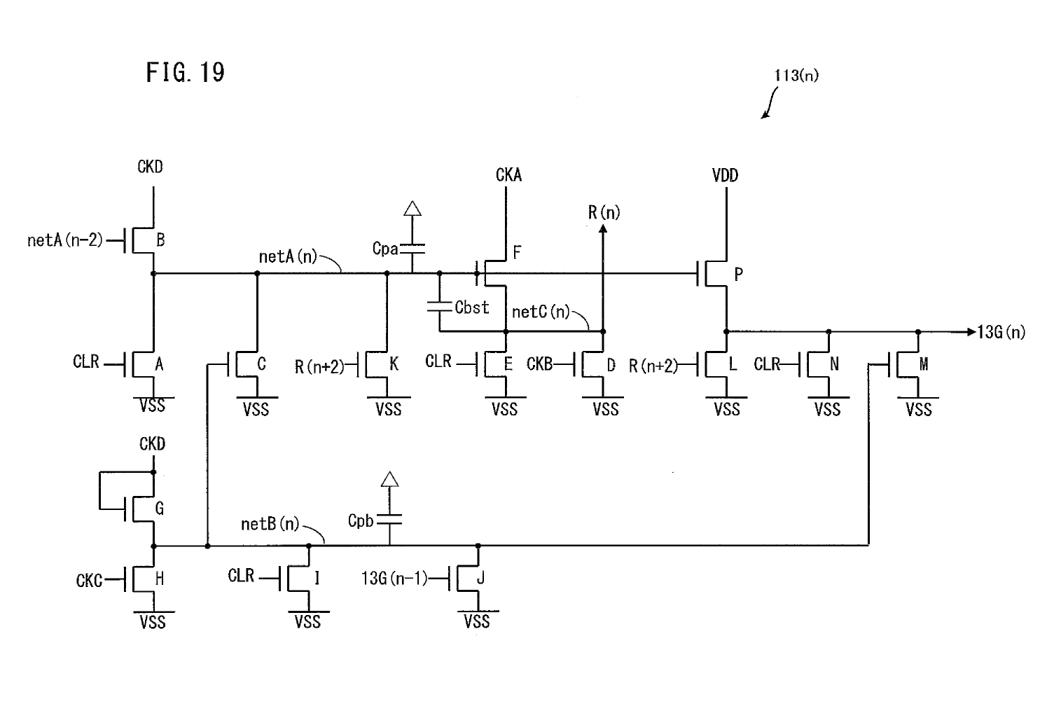

Next, the following describes operations of the driving circuit 112(n). FIG. 18 is a timing chart when the driving circuit 112(n) drives the gate line 13G(n). Hereinafter, operations of the driving circuit 112(n) different from those in Embodiment 2 are described with reference to FIGS. 18 and 16.

At a time t4 in FIG. 18, the potential of the netA(n+2) rises to H level, and the gate line 13G(n+2) transitions to the selected state, which causes the TFT-L and the

TFT-K to be turned ON. Here, since the clock signal CKA has a potential at the L level, a potential at the L level (VSS) is applied to the gate line 13G(n) through the TFT-L. Further, the potential of the netA(n) is pulled down to the L level (VSS) through the TFT-K.

After a time t6, since the potential of the netA(n+2) is at the L level, the TFT-L is turned OFF, the TFT-D is turned ON at a timing when the potential of the clock signal CKB rises to the H level, whereby the potential of the gate line 13G(n) is maintained at the L level through the TFT-D. Further, after the time t6, the potential of the gate line 13G(n+2) is at the L level and the TFT-K is turned OFF, but at a timing when the potential of the clock signal CKD rises to the H level, the H-level potential is input to the netB(n) through the TFT-G. This causes the TFT-C to be turned ON, and the potential of the netA(n) is maintained to the L level.

In a case where the driving circuit 112 is arranged in the display region, the lines 15L for supplying the clock signals and the power source voltage signal are provided at the pixels. Therefore, as compared with a case where the driving circuit 112 is arranged outside the display region, the parasitic capacitance between the line 15L and the gate line 13G increases, which results in that when the gate line 13G is caused to transition to the non-selected state, the gate line 13G cannot be surely put into the non-selected state in some cases. In Embodiment 3 mentioned above, the netA(n+2) is connected to the gate terminal of the TFT-L that outputs a non-selection voltage to the gate line 13G(n) so as to increase the gate voltage of the TFT-L, whereby the driving power of the TFT-L can be increased. Therefore, during a period while the gate line trasitions to the non-selected state, the gate line 13G(n) can be surely put into the non-selected state.

### Embodiment 4

In the foregoing descriptions of Embodiments 1 to 3, examples are described in which clock signals are input to the drain terminal of the TFT functioning as an output unit, and the drain terminal of the TFT functioning as a gate line discharge unit, so that the gate line is charged using the clock signals. In this description of the present embodiment, an example is described in which charging is performed by using a direct current voltage signal at the H level (VDD).

### (Circuit Configuration)

FIG. 19 illustrates an exemplary equivalent circuit of a driving circuit 113 in the present embodiment. As illustrated in FIG. 19, a driving circuit 113(n) that drives the gate line 13G(n) is different from the driving circuit of the application example of Embodiment 1 regarding the following points.

The driving circuit 113(n) includes a TFT-P, a netC(n) as an internal line, a TFT-N, and a TFT-M.

The source terminal of the TFT-F, the capacitor Cbst, the drain terminal of the TFT-E, and the drain terminal of the TFT-D are connected to the netC(n), and the potential R(n) of the netC(n) is supplied to the gate terminal of the TFT-L of the driving circuit 113(n−2).

The TFT-F outputs the potential of the clock signal CKA to the netC(n) according to the potential of the netA(n), thereby to charge the capacitor Cbst.

The TFT-E pulls down the potential of the netC(n) to the L level according to the potential of the reset signal CLR input to the gate terminal.

The TFT-D pulls down the potential of the netC(n) to the L level according to the potential of the clock signal CKB input to the gate terminal.

Regarding the TFT-L, the potential R(n+2) of the netC in the driving circuit 113(n+2) that drives the gate line 13G(n+2) is input to the gate terminal of the TFT-L. The TFT-L applies the non-selection voltage to the gate line 13G(n) according to the potential R(n+2), thereby to pull down the potential of the gate line 13G(n) to the L level.

Regarding the TFT-N, the reset signal CLR is supplied to the gate terminal thereof, the gate line 13G(n) is connected to the drain terminal thereof, and the power source voltage signal VSS is input to the source terminal thereof. The TFT-N applies the non-selection voltage to the gate line 13G(n) according to the potential of the reset signal CLR, thereby to pull down the potential of the gate line 13G(n) to the L level.

Regarding the TFT-M, the netB(n) is connected to the gate terminal thereof, the gate line 13G(n) is connected to the drain terminal thereof, and the power source voltage signal VSS is input to the source terminal thereof. The TFT-M applies the non-selection voltage to the gate line 13G(n) according to the potential of the netB(n), thereby to pull down the potential of the gate line 13G(n) to the L level.

Regarding the TFT-P, the gate terminal thereof is connected with the netA(n), a direct current voltage signal at the H level (VDD) is input to the drain terminal thereof, and the source terminal thereof is connected to the gate line 13G(n). The TFT-P charges the gate line 13G(n) so that the gate line 13G(n) has a potential at the H level (VDD) according to the potential of the netA(n), thereby to switch the gate line 13G(n) into the selected state.

In other words, in the present embodiment, the TFT-P functions as an output unit, and the TFT-F and the capacitor Cbst function as a boosting unit. Further, the TFT-L, the TFT-M, and the TFT-N function as a gate line discharge unit.

### (Exemplary Arrangement)

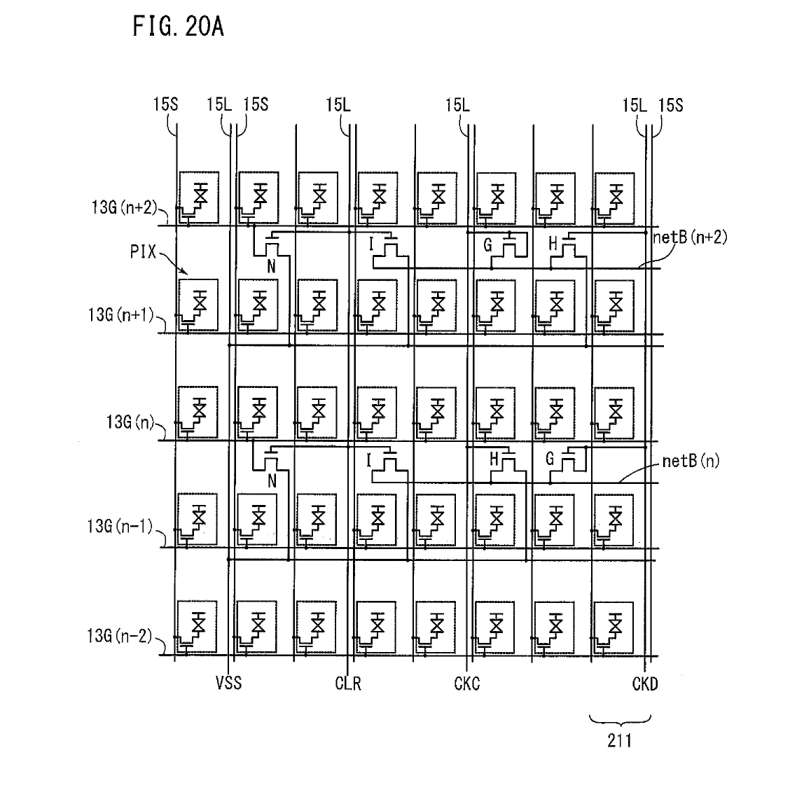

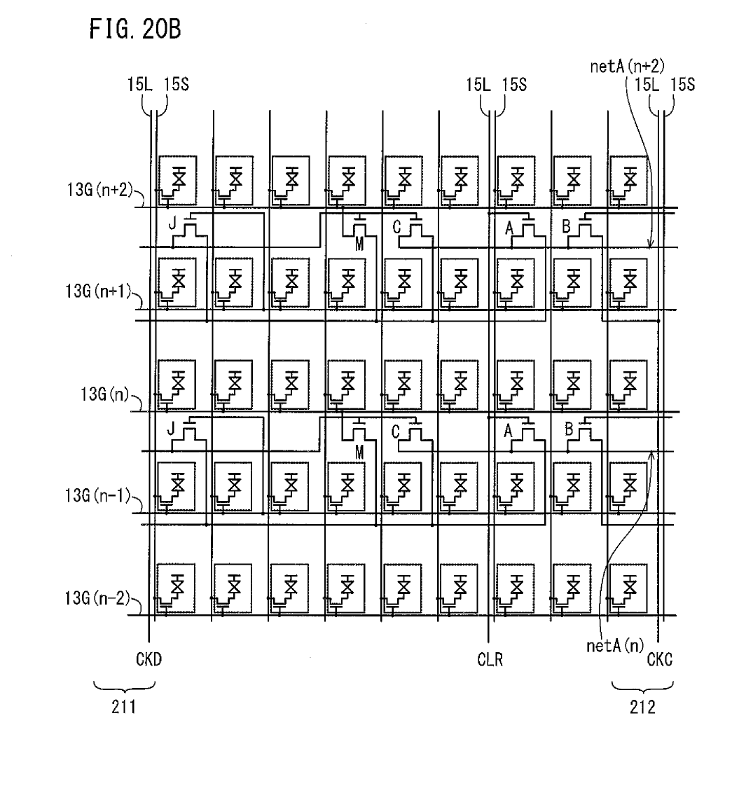

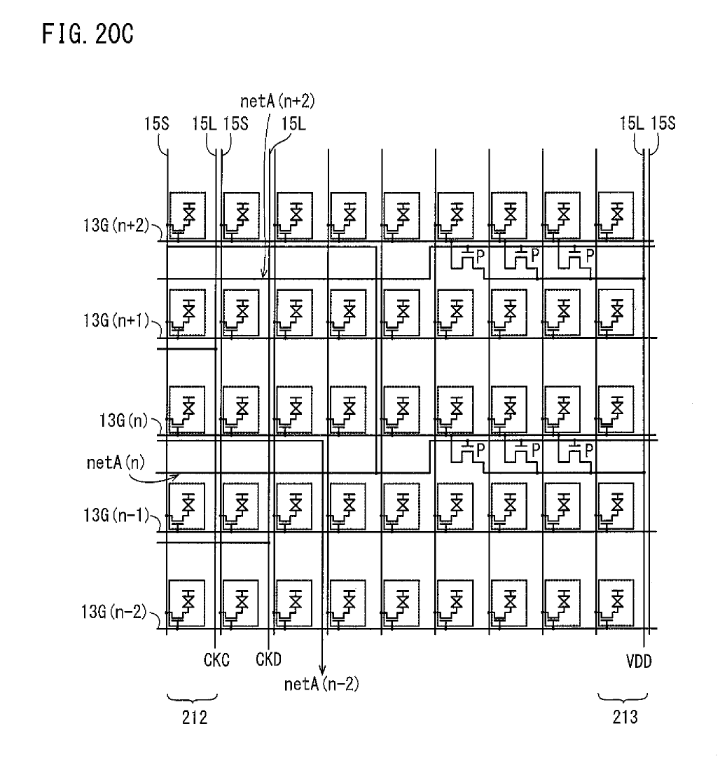

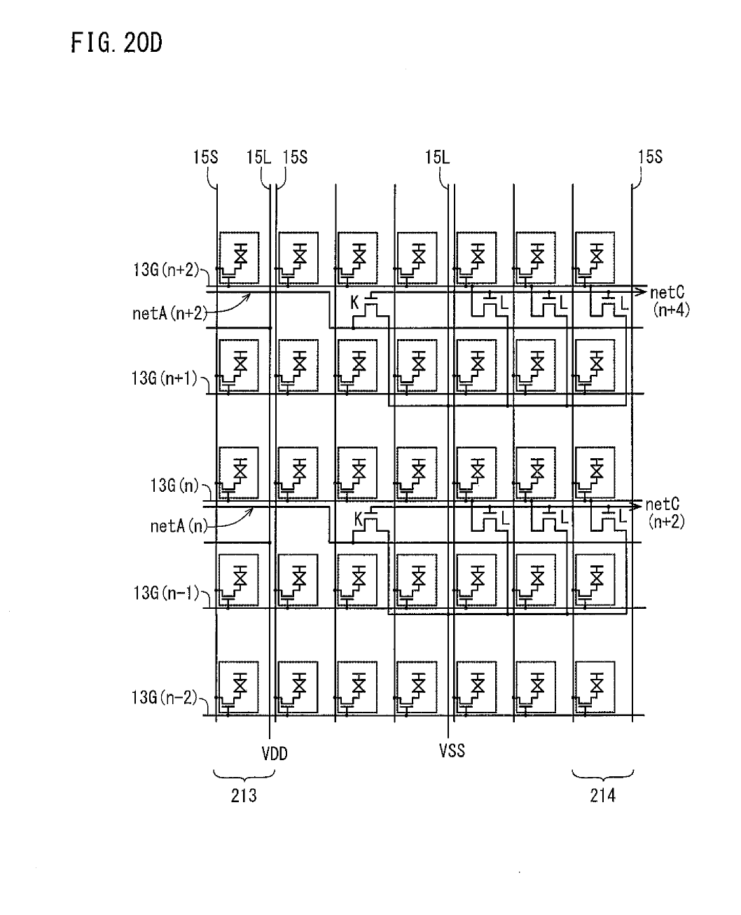

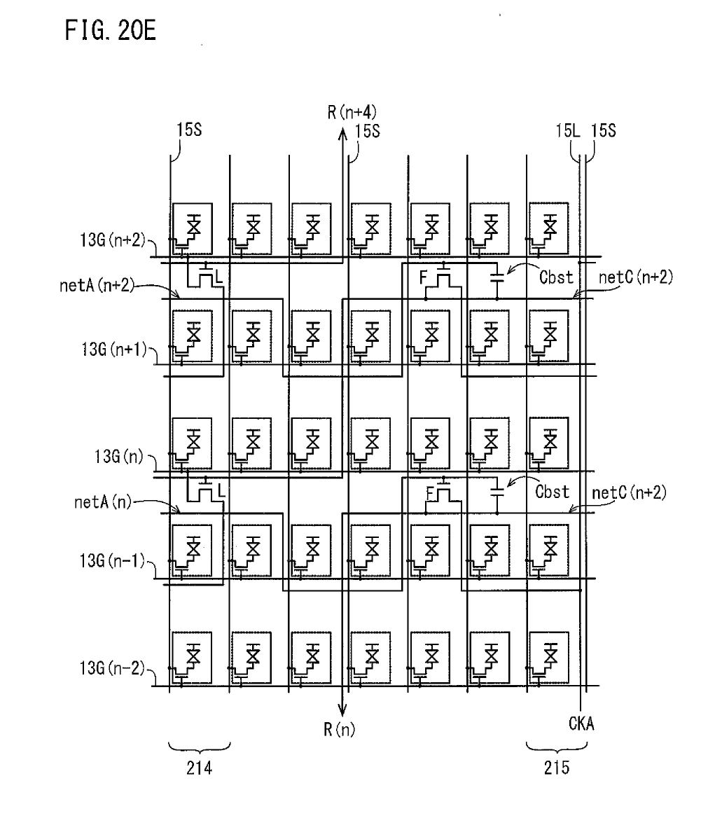

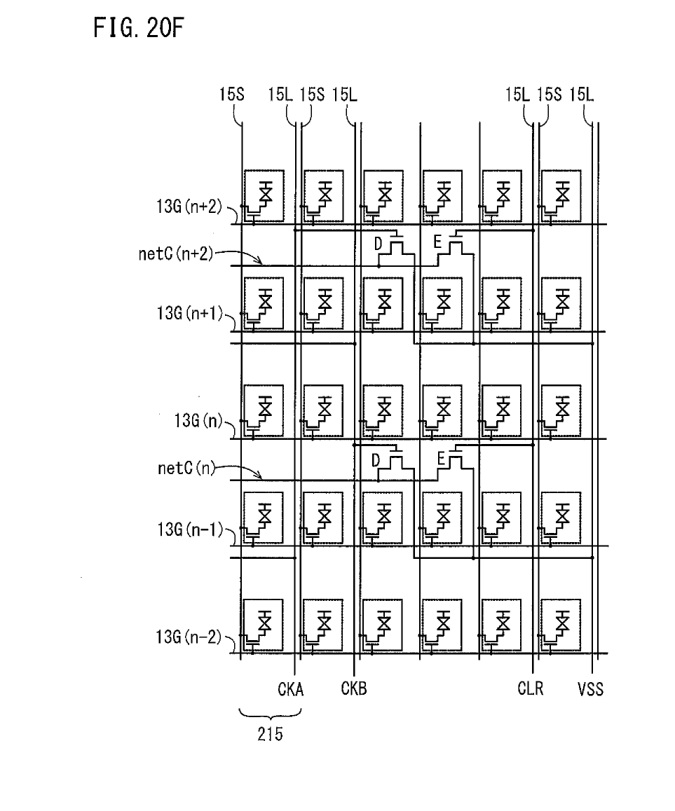

Next, the following describes an exemplary arrangement of the driving circuits 11 in the display region in the present embodiment. FIGS. 20A to 20F are schematic diagrams illustrating an exemplary arrangement of the driving circuit 113(n) and the driving circuit 113(n+2) in the display region. FIGS. 20A to 20F are continuous over the columns 211 to 215. Further, in each drawing, for convenience sake, the descriptions of “TFT-” are omitted, but the TFTs indicated by “A” to “N”, “P” in each drawing correspond to the TFT-A to the TFT-N, and the TFT-P in FIG. 19, respectively. The following description principally describes the arrangement of configurations different from those in the application example of Embodiment 1.

In FIGS. 20A to 20F, respective elements of the driving circuit 113(n) are arranged in spaces from the gate line 13G(n) to the gate line 13G(n−2), and respective elements of the driving circuit 113(n+2) are arranged in spaces from the gate line 13G(n+2) to the gate line 13G(n).

As illustrated in FIG. 20A, regarding the TFT-N and the TFT-I in each of the driving circuit 113(n) and the driving circuit 113(n+2), the line 15L that supplies the reset signal CLR is connected to the gate terminals of these TFTs-N and -I. Further, as illustrated in FIG. 20B, the gate terminal of the TFT-M in the driving circuit 113(n) is connected with the netB(n), the gate terminal of the TFT-M in the driving circuit 113(n+2) is connected with the netB(n+2). Still further, the source terminals of the TFTs-M in the driving circuit 113(n) and the driving circuit 113(n+2) are connected to the line 15L that supplies the power source voltage signal VSS, illustrated in FIG. 20A.

In the present embodiment, as illustrated in FIG. 20C, the TFT-P functioning as an output unit is composed of three TFTs-P connected in parallel. In FIG. 20C, the line 15L that supplies the direct current voltage signal at the H level (VDD) is provided to respective pixels where the TFTs-P are arranged, and is connected to the respective drain terminals of the TFTs-P.

Further, as illustrated in FIG. 20D, in the present embodiment, the TFT-L functioning as a gate line discharge unit is composed of three TFTs-L connected in parallel. As illustrated in FIGS. 20D and 20E, the respective gate terminals of the TFTs-L in the driving circuit 113(n) are connected with the netC(n+2) in the driving circuit 113(n+2), and the potential R(n+2) of the netC(n+2) is supplied thereto. Still further, the respective gate terminals of the TFTs-L in the driving circuit 113(n+2) are connected with a netC(n+4) in a driving circuit 113(n+4), which is not illustrated, and a potential R(n+4) of the netC(n+4) is supplied thereto. Still further, as illustrated in FIG. 20D, the line 15L that supplies the direct current voltage signal at the L level (VSS) is provided to respective pixels where the TFTs-L in the driving circuit 113(n) and the driving circuit 113(n+2) are arranged, and is connected to the respective source terminals of the TFTs-L.

In the description of the present embodiment, an example is described in which, as illustrated in FIG. 20E, the TFT-F functioning as a boosting unit is composed of one TFT, but the TFT-F may be composed of a plurality of TFTs connected in parallel. In FIG. 20E, a netC(n) to which the source terminal of the TFT-F and one of electrodes of the capacitor Cbst in the driving circuit 113(n) are connected is connected to a gate terminal of a TFT-L in a driving circuit 113(n−2) that is not illustrated, and a potential R(n) is supplied to the gate terminal. Further, as illustrated in FIG. 20F, drain terminals of the TFT-E and the TFT-D in the driving circuit 113(n) are connected to the netC(n) that is connected to one electrode of the capacitor Cbst. The drain terminals of the TFT-E and the TFT-D in the driving circuit 113(n+2) are similarly connected to the netC(n+2) that is connected with one of electrodes of a capacitor Cbst.

### (Exemplary Operation)

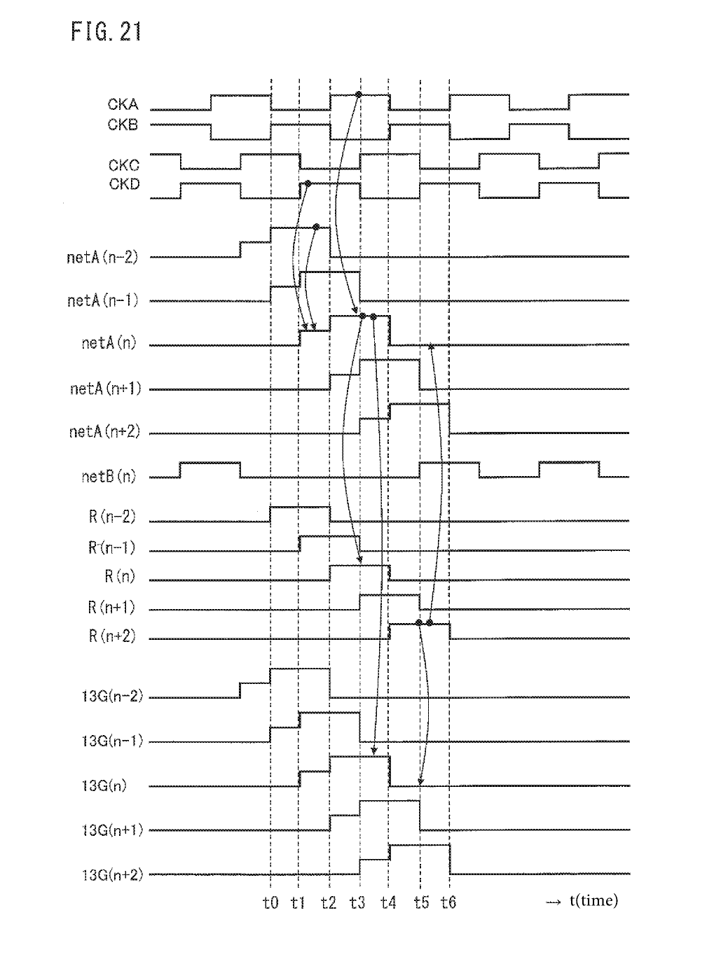

Next, the following describes operations of the driving circuit 113(n). FIG. 21 is a timing chart when the driving circuit 113(n) drives the gate line 13G(n). Hereinafter, operations different from those in the application example of Embodiment 1 are described with reference to FIGS. 21 and 19.

At a time t1, the potential of the clock signal CKD rises to the H level, and the potential of the netA(n−2) is at the H level. At the time t1, therefore, the TFT-B is in an ON state, and through the TFT-B, the H level (VDD) potential of the clock signal CKD is precharged to the netA(n). This causes the TFTs-P to be turned ON, thereby causing the gate line 13G(n) to be charged so as to have a potential of (the VDD minus the threshold voltage of the TFT-P), through the TFTs-P. Further, the TFT-F is turned ON here, but since the potential of the clock signal CKA is at the L level, the potential R(n) of the netC(n) is maintained at the L level.

At a time t2, the potential of the clock signal CKA rises to the H level. The TFT-F is turned ON at the time t1, and through the TFT-F, the H-level potential of the clock signal CKA is supplied to the netC(n). Then, as the potential of the netC(n) rises, the potential of the precharged netA(n) is boosted up through the capacitor Cbst, thereby being charged so as to have a potential greater than the potential of (the VDD plus the threshold voltage of the TFTs-P) (hereinafter, this is referred to as main charge). With this, a gate voltage greater than the threshold voltage is applied to the TFTs-P, and through the TFTs-P, the potential at the H level (VDD) is supplied to the gate line 13G(n). Thus, during a period from the time t2 to the time t4, the gate line 13G(n) trasitions to the selected state.

At the time t4, the potential R(n+2) of the netC(n+2) in the driving circuit 113(n+2) rises to the H level, the TFT-K and the TFTs-L in the driving circuit 113(n) are turned ON. With this, the potential of the netA(n) is pulled down to the L level (VSS) through the TFT-K, and through the TFTs-L, a potential at the L level (VSS) is applied to the gate line 13G(n).

Since the potential R(n+2) falls to the L level after a time t6, the TFT-K and the TFTs-L are turned OFF, but since the H-level potential is supplied to the netB(n) at a timing when the potential of the clock signal CKD rises to the H level, the potential of the netA(n) is maintained at the L level through the TFT-C, and the potential of the gate line 13G(n) is maintained at the L level through the TFT-M.

In Embodiment 4 described above, since the gate line 13G is charged by using the direct current voltage signal having the potential at the H level (VDD) corresponding to the selection voltage, the load of supplying the clock signals to the driving circuit 113 can be reduced, whereby the electric power consumption can be reduced. Further, in Embodiment 4, since the TFTs-P are added in the driving circuit 113, the parasitic capacitance Cpa of the netA in the driving circuit 113 further increases, which causes the efficiency of the rise of the potential of the netA by the capacitor Cbst to decrease. However, by connecting the netA(n−2) to the gate terminal of the TFT-B for precharge, the decrease in the efficiency of the rise of the potential of the netA is prevented, as compared with the case of the diode-connection of the TFT-B. As a result, in the driving circuit 113, a high gate voltage is applied to the TFTs-P, which increases the driving power of the TFTs-P, thereby enabling the driving circuit 113 to stably operate.

### Embodiment 5

While an example in which M gate lines 13G are sequentially driven is described in the foregoing description of Embodiment 4, the description of the present embodiment describes an example in which any gate lines 13G are driven.

### Circuit Configuration

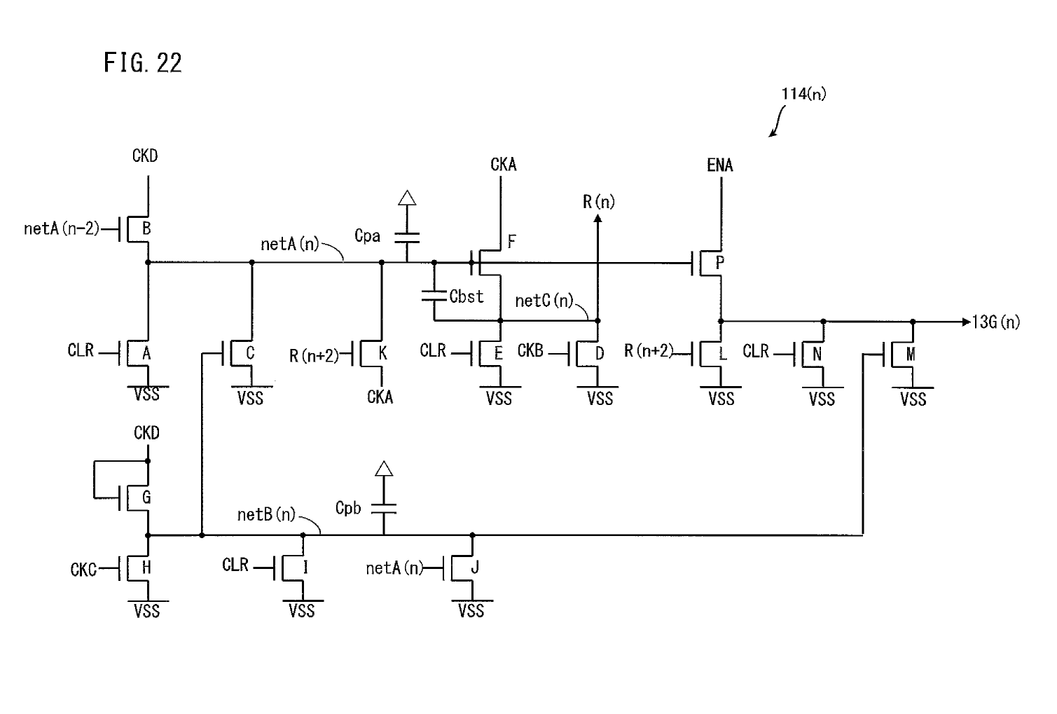

FIG. 22 illustrates an exemplary equivalent circuit of a driving circuit 114 in the present embodiment. A driving circuit 114(n) that drives a gate line 13G(n) illustrated in FIG. 22 is different from the driving circuit 113(n) in Embodiment 4 regarding the following points.

Regarding the TFTs-P in the driving circuit 114(n), a row selection signal ENA is input to the drain terminals thereof. Further, regarding the TFT-K, the netA(n+2) is connected to the gate terminal thereof, and the clock signal CKA is input to the drain terminal thereof.

Regarding the TFT-J, the netA(n+2) is connected to the gate terminal thereof. The adjacent gate line 13G(n−1) is connected to the gate terminal of the TFT-J in Embodiments 1 to 4 described above, but in the present embodiment, the adjacent gate line 13G(n−1) is not driven in some cases. On that account, in the present embodiment, the driving circuit 114 has such a configuration that, to the gate terminal of the TFT-J, the potential of a gate line 13G adjacent thereto should not be supplied.

The row selection signal is a signal having a potential at the H level (VDD) or a potential at the L level (VSS). The display control circuit 4 (see FIGS. 1 and 3) supplies, as control signals, the clock signals as well as any one of the row selection signals ENA, ENB, ENC, END additionally, to the drain terminals of the TFTs-P in each of the driving circuits.

### (Exemplary Arrangement)

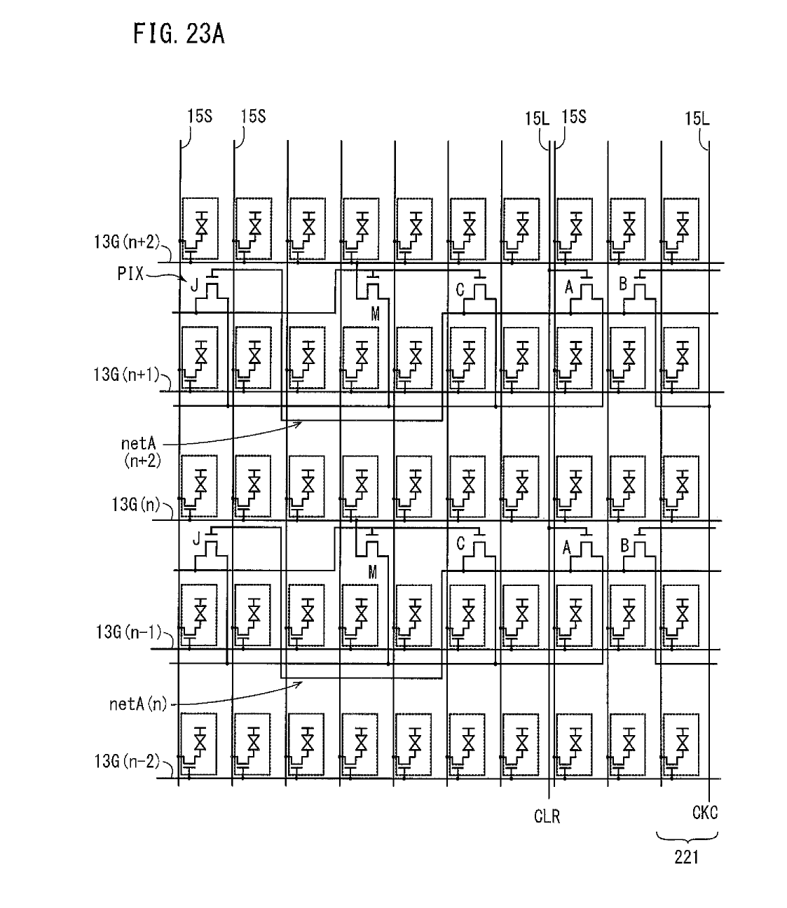

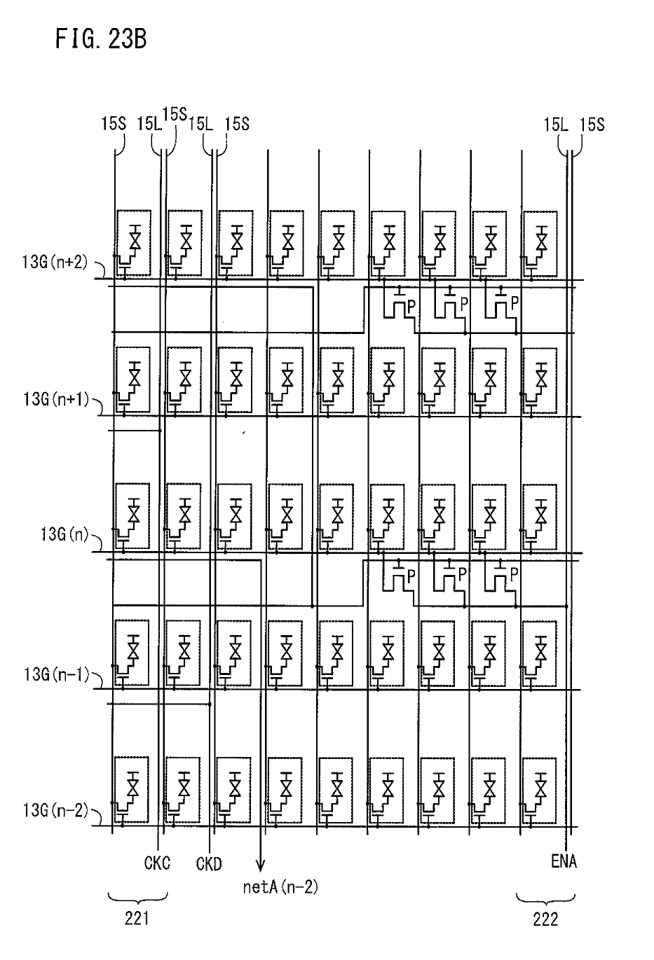

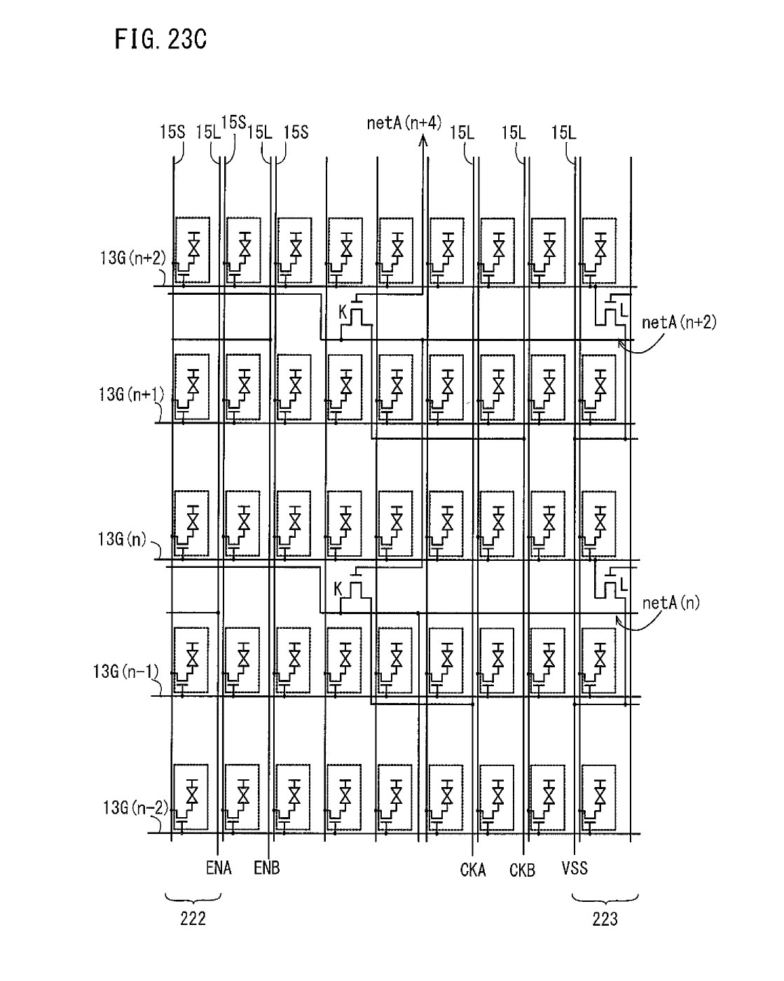

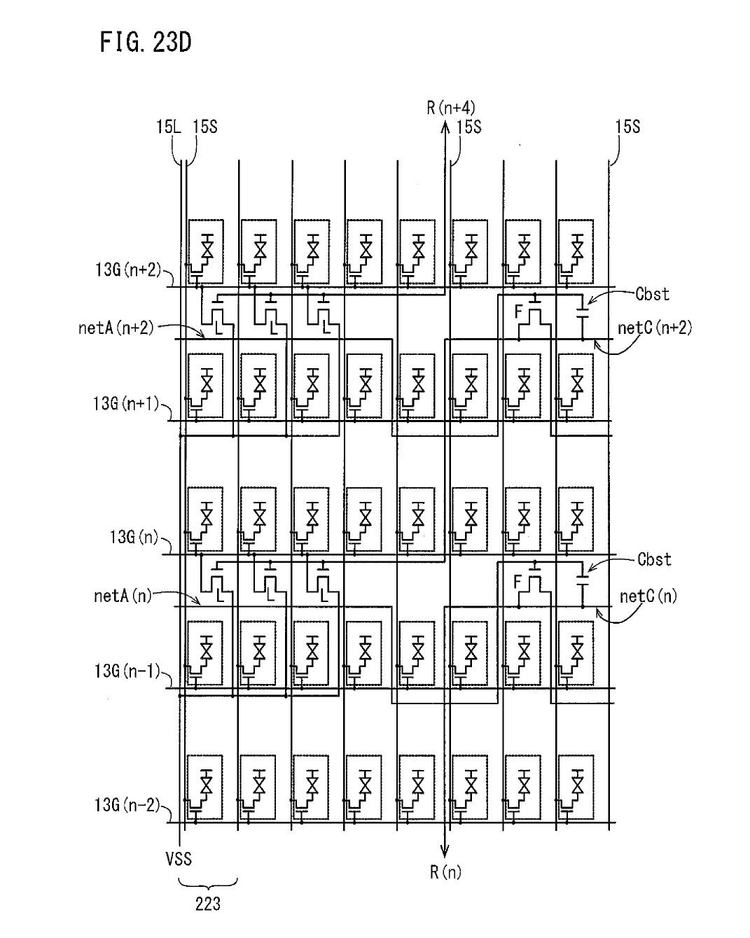

FIGS. 23A to 23D are schematic diagrams illustrating the display region in which some of elements of the driving circuit 114(n) and the driving circuit 114(n+2) that drives the gate line 13G(n+2), including the TFTs-J, the TFTs-K, and the TFTs-P thereof, are arranged. FIGS. 23A to 23D are continuous over the columns 221 to 223. Further, in FIGS. 23A to 23D, for convenience sake, the descriptions of “TFT-” are omitted, but the TFTs indicated by alphabetic characters in each drawing correspond to the TFTs indicated by the same alphabetic characters in FIG. 22, respectively.

As illustrated in FIG. 23A, the gate terminal of the TFT-J in the driving circuit 114(n) is connected with the netA(n), and the gate terminal of the TFT-J in the driving circuit 114(n+2) is connected with the netA(n+2).

Further, as illustrated in FIG. 23B, the drain terminal of each TFT-P in the driving circuit 114(n) is connected to the line 15L to which the row selection signal ENA is supplied. On the other hand, the drain terminal of each TFT-P in the driving circuit 114(n+2) is connected to the line 15L to which the row selection signal ENB is supplied, as illustrated in FIG. 23C.

Though illustration is omitted, the drain terminals of the TFTs-P in the driving circuit 114(n−1) that drives the gate line 13G(n−1) are connected to the line 15L to which the row selection signal END is supplied. Further, the drain terminals of the TFTs-P in the driving circuit 114(n+1) that drives the gate line 13G(n+1) are connected to the line 15L to which the row selection signal ENC is supplied. Further, the drain terminals of the TFTs-P in the driving circuit 114(n−2) that drives the gate line 13G(n−2) are connected to the line 15L to which the row selection signal ENB is supplied.

As illustrated in FIGS. 23C and 23D, the gate terminal of the TFT-K in the driving circuit 114(n) is connected to the netA(n+2) in the driving circuit 114(n). The gate terminal of the TFT-K in the driving circuit 114(n+2) is connected to a netA(n+4) in a driving circuit 114(n+4), which is not illustrated in the drawing.

Further, as illustrated in FIG. 23D, in the present embodiment, the netC is not connected to the gate terminal of the TFT-K, but the netC is connected to the gate terminals of the TFTs-L. Thus, as compared with Embodiment 4 in which the netC is connected to the gate terminals of the TFT-K and the TFTs-L, the line of the netC is shorter.

### (Exemplary Operation)

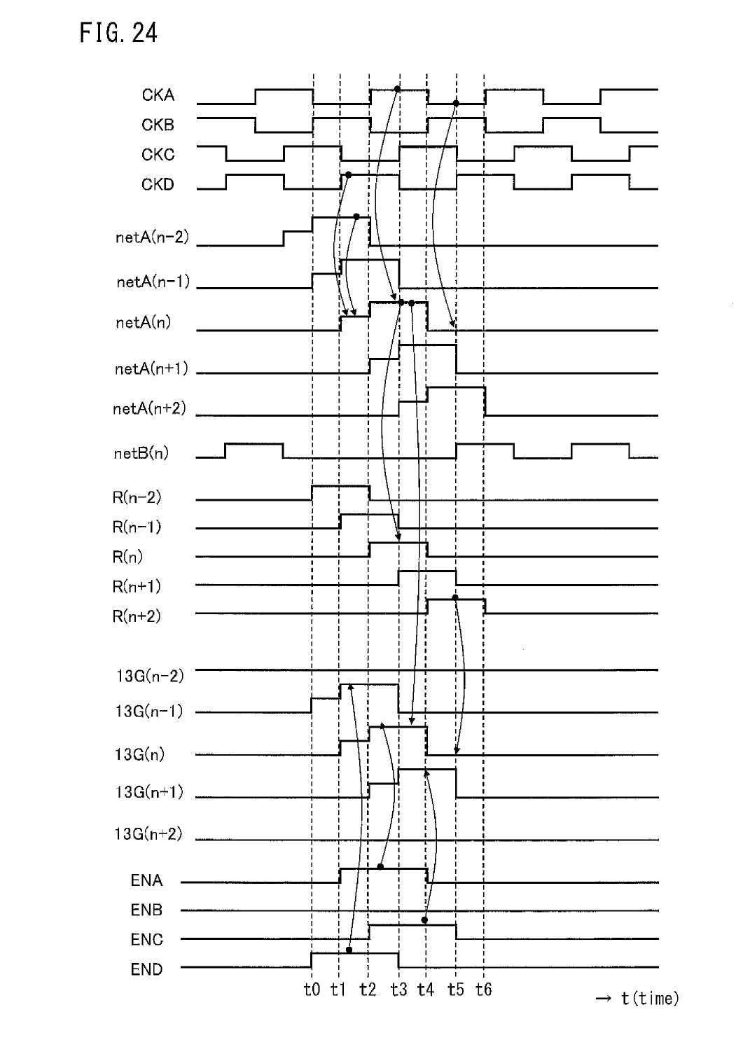

Next, the following describes operations of the driving circuit in the present embodiment. FIG. 24 is a timing chart when part of the gate lines 13G are driven in one frame. Hereinafter, operations different from those in Embodiment 4 are described.

The display control circuit 4 (see FIG. 1 or FIG. 3) outputs the row selection signals ENA to END so that, in one frame, the gate lines 13G(n−1) to 13G(n+1) are driven and the gate lines 13G(n−2) and 13G(n+2) are not driven. More specifically, during a period from a time tO to a time t3 illustrated in FIG. 24, the display control circuit 4 outputs the row selection signal END having an H-level potential, and during a period from the time t1 to the time t4, outputs the row selection signal ENA having the H-level potential. Further, the display control circuit 4 outputs the row selection signal ENC having the H-level potential during a period from a time t2 to a time t5, and outputs the row selection signal ENB having a L-level potential during one frame.

In FIG. 24, the netA(n−2) is charged (main charge) during a period from a time tO to the time t2, and at the time t1, when the potential of the clock signal CKD rises to the H level, the TFT-B in the driving circuit 114(n) is turned ON, which causes the netA(n) to be precharged to have a potential at the H level (VDD) through the TFT-B. This causes the TFTs-P to be turned ON. Here, since the row selection signal ENA has a potential at the H level (VDD), the gate line 13G(n) is charged so as to have the potential of (the VDD minus the threshold voltage of the TFT-P) through the TFTs-P. Further, here, the TFT-F is turned ON also, but since the potential of the clock signal CKA is at the L level, the potential R(n) of the netC(n) is maintained at the L level.

When the TFT-F is in the ON state, the potential R of the netC in the each driving circuit 114 rises to the H level, according to the potential of the clock signal input to the drain terminal of the TFT-F. In this example, as illustrated in FIG. 24, the potentials R(n−2), R(n−1), R(n), R(n+1), R(n+2) rise to the H level at timings when the potentials of the clock signals CKB, CKD, CKA, CKC, CKD rise to the H level, respectively.

From the time tO to the time t2, along with the rise of the potential R(n−2), the potential of the netA(n−2) is boosted up by the capacitor Cbst, whereby the netA(n−2) is being charged (main charge). Here, since the row selection signal ENB has a potential at the L level, the L-level potential is supplied to the gate line 13G(n−2) through the TFTs-P in the driving circuit 114(n−2), whereby the gate line 13G(n−2) maintains the non-selected state.

Further, from the time t1 to the time t3, the netA(n−1) is charged (main charge) along with the rise of the potential R(n−1), as is the case with the netA(n−2) described above. Here, since the row selection signal END has a potential at the H level, the H-level potential is supplied to the gate line 13G(n−1) through the TFTs-P in the driving circuit 114(n−1), whereby the gate line 13G(n−1) trasitions to the selected state.

Similarly, from the time t2 to the time t4, the netA(n) is charged (main charge) along with the rise of the potential R(n). Here, since the row selection signal ENA has a potential at the H level, the gate line 13G(n) trasitions to the selected state. Further, from the time t3 to the time t5, the netA(n+1) is charged (main charge) along with the rise of the potential R(n+1). Here, the row selection signal ENC has a potential at the H level, and the gate line 13G(n+1) trasitions to the selected state.

From the time t4 to the time t6, the netA(n+2) is charged (main charge) along with the rise of the potential R(n+2), but the row selection signal ENB has a potential at the L level, whereby the gate line 13G(n+2) maintains the non-selected state.

In Embodiment 5 described above, any gate lines 13G can be driven by inputting the row selection signal to the drain terminals of the TFTs-P in the driving circuit 114. This makes it possible to, for example, drive only a plurality of consecutive gate lines with a certain set frequency, and drive the other gate lines 13G with a frequency lower than the foregoing frequency. As a result, as compared with a case where all of the gate lines 13G are driven with a uniform frequency, the electric power consumption upon driving the gate lines can be reduced. Further, the data signals may be input only to the rows where the display data should be updated, which makes it possible to reduce the electric power consumption upon driving the source lines 15S.

### MODIFICATION EXAMPLE

Embodiments of the present invention are described above. The embodiments described above, however, are merely examples for implementing the present invention. The present invention, therefore, is not limited to the above-described embodiments, and can be implemented by appropriately changing or combining the above-described embodiments without departing the scope of the invention. Hereinafter, modifications of the present invention are described.

(1) In the foregoing description of Embodiment 1, an example is described in which four-phase clock signals having different phases are used, but alternatively, two-phase clock signals may be used. Hereinafter, regarding a case where two-phase clock signals are used, points principally different from Embodiment 1 are described.

### (Configuration of Active Matrix Substrate)

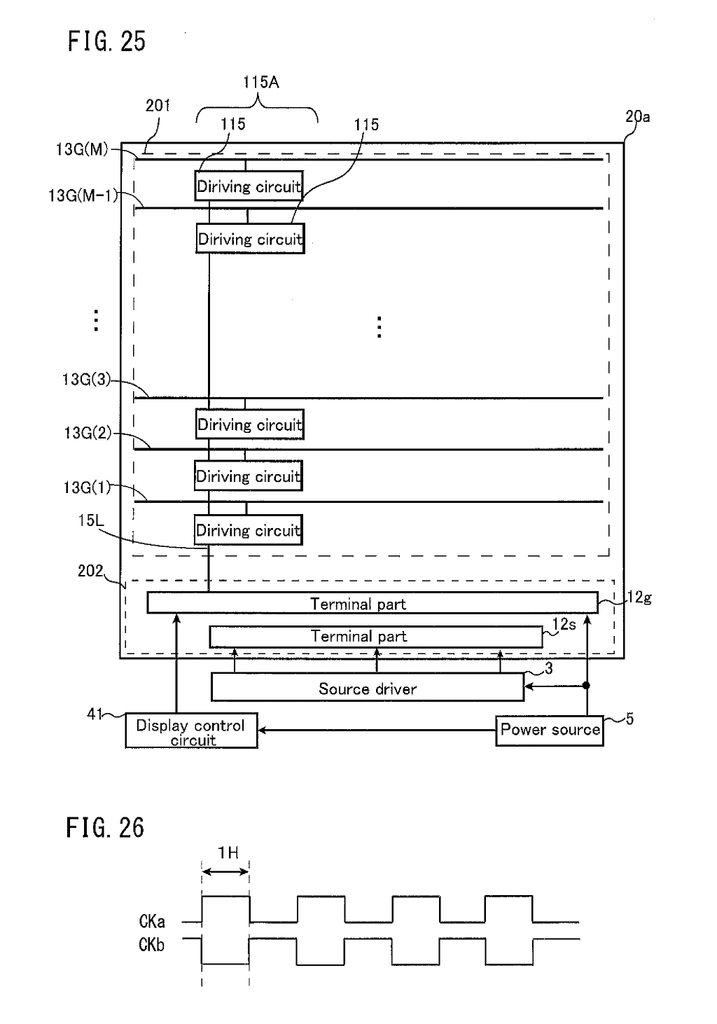

FIG. 25 schematically illustrates a schematic configuration of an active matrix substrate in the present modification example. In FIG. 25, the illustration of the source lines 15S (see FIG. 2) is omitted. As illustrated in FIG. 2, in the present modification example, in the display region 201 on the active matrix substrate 20a, a gate driver 115A is provided in which one driving circuit 115 is provided per one gate line 13G. The driving circuits 115 are connected with one another through the line 15L.

The display control circuit 41 outputs, as control signals, two-phase clock signals CKa, CKb illustrated in FIG. 26 to the terminal part 12g. The clock signals CKa, CKb are signals whose potentials repetitively rise and fall to the H level (VDD) and the L level (VSS) every horizontal scanning period, as illustrated in FIG. 26.

### (Circuit Configuration)

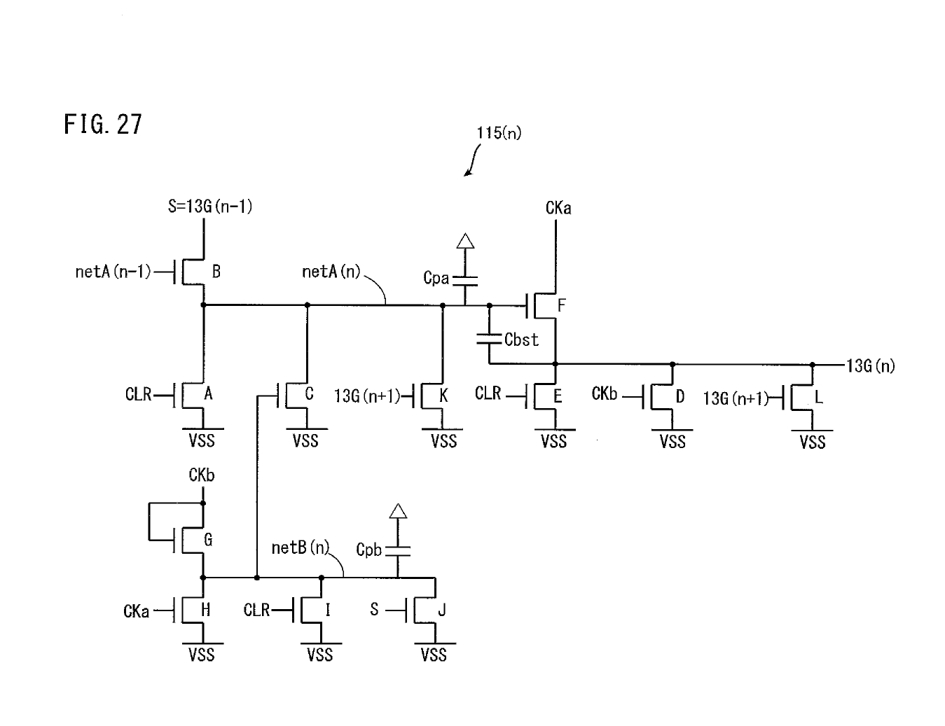

FIG. 27 illustrates an exemplary equivalent circuit of the driving circuit 115. As illustrated in FIG. 27, the driving circuit 115(n) that drives the gate line 13G(n) has the same configuration as that of the driving circuit 11 except that the clock signals input to the TFT-F, the TFT-G, and the TFT-H, which compose the driving circuit 11 in Embodiment 1, the potential of the netA input to the gate terminal of the TFT-B, and the potential of the gate line 13G input to the gate terminals of the TFT-K and the TFT-L are different. In other words, in the present embodiment, a clock signal CKa is input to the drain terminal of the TFT-F. To the gate terminal and the drain terminal of the TFT-G, a clock signal CKb is input. To the gate terminal of the TFT-H, a clock signal CKa is input. To the gate terminal of the TFT-B, a potential of the netA(n−1) in the driving circuit 115(n−1) that drives the gate line 13G(n−1) is supplied. To the gate terminals of the TFT-K and the TFT-L, the potential of the gate line 13G(n+1) is supplied

### (Exemplary Arrangement)

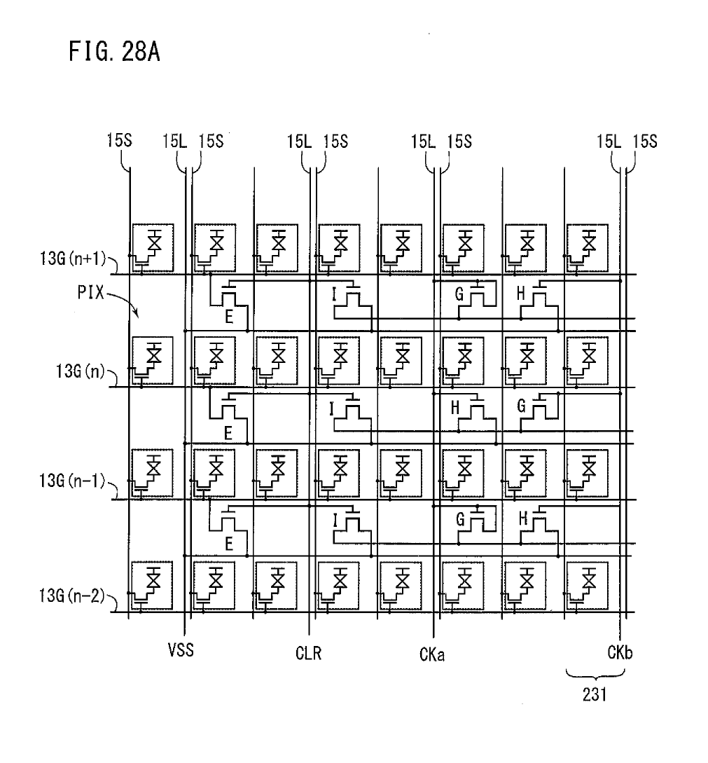

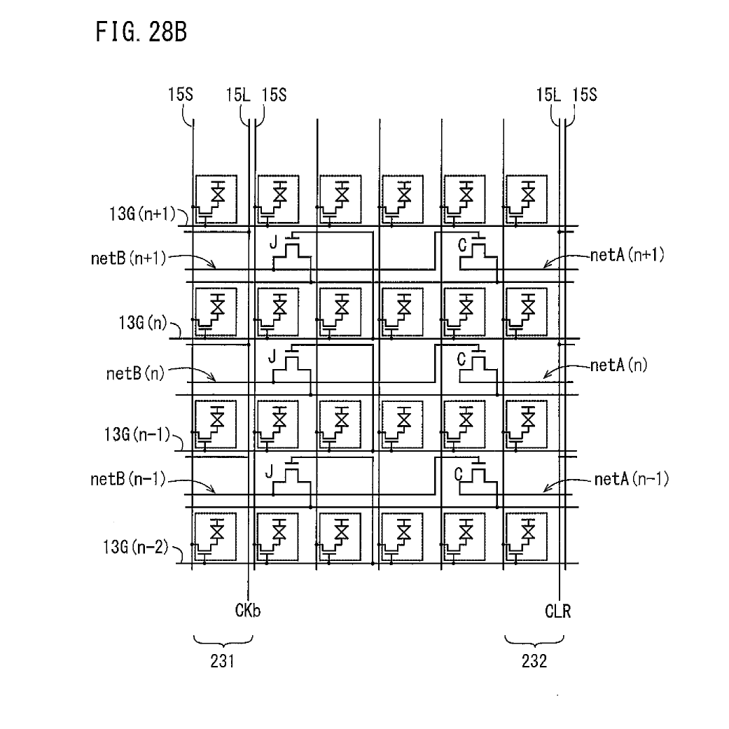

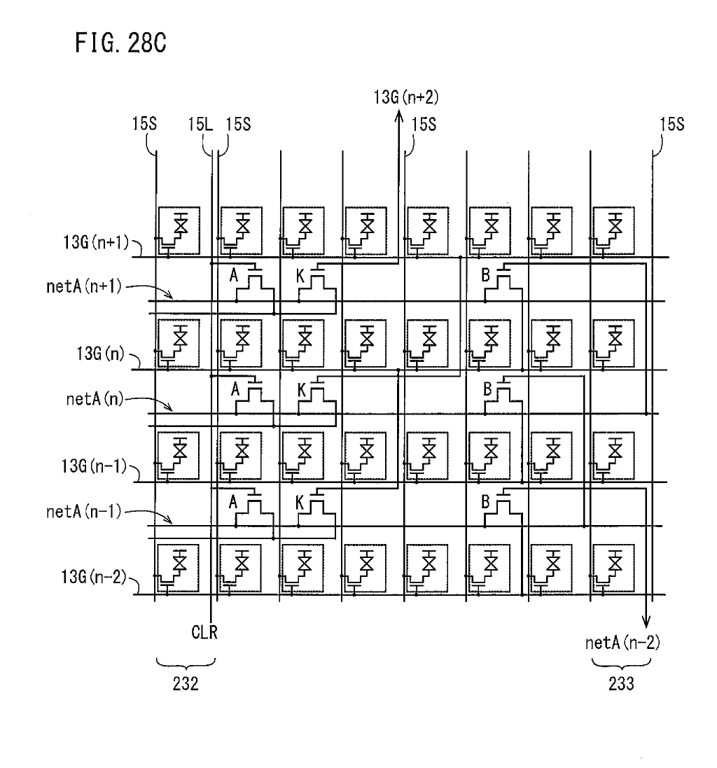

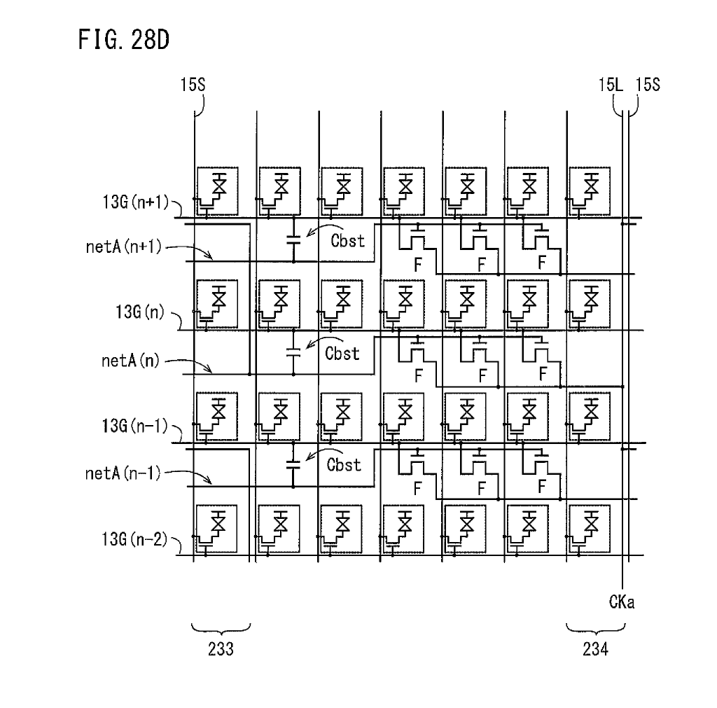

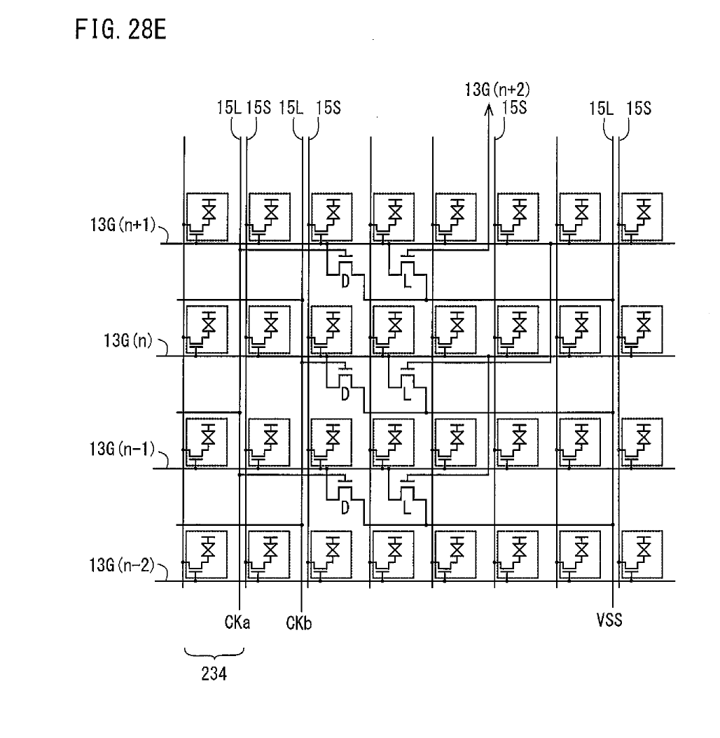

Next, the following describes an exemplary arrangement of the driving circuits 115 in the display region. FIGS. 28A to 28E schematically illustrate pixels where the driving circuit 115(n−1), the driving circuit 115(n), and the driving circuit 115(n+1) that drive the gate lines 13G(n−1) to 13G(n+1), respectively are arranged. In FIGS. 28A to 28E, for convenience sake, the descriptions of “TFT-” are omitted, but the TFTs indicated by “A” to “L” in FIGS. 28A to 28E correspond to the TFT-A to TFT-L illustrated in FIG. 27, respectively. Further, FIGS. 28A to 28E are continuous over the columns 231 to 234.

In FIGS. 28A to 28E, each element composing the driving circuit driving circuit 115(n−1) is arranged in the space between the gate lines 13G(n−1) and the gate line 13G(n−2), and each element composing the driving circuit 115(n) is arranged in the space between the gate lines 13G(n−1) and the gate line 13G(n). Further, each element composing the driving circuit driving circuit 115(n+1) is arranged in the space between the gate lines 13G(n) and the gate line 13G(n+1).

In FIG. 28A, the gate terminals and the drain terminals of the TFTs-G in the driving circuit 115(n−1) and the driving circuit 115(n+1) are connected to the line 15L to which the clock signal CKa is supplied. Further, the gate terminals of the TFTs-H in the driving circuit 115(n−1) and the driving circuit 115(n+1) are connected to the line 15L to which the clock signal CKb is supplied. The gate terminals of the TFT-G and the TFT-H in the driving circuit 115(n) are connected to the line 15L to which a clock signal having a phase opposite to that of the clock signal supplied to the TFTs-G and TFTs-H in the driving circuit 115(n−1) and the driving circuit 115(n+1) is supplied.

Further, in FIG. 28C, the gate terminal of the TFT-K in the driving circuit 115(n+1) is connected to a gate line 13G(n+2), which is not illustrated in the drawing, and the gate terminal of the TFT-K in the driving circuit 115(n) is connected to the gate line 13G(n+1). The gate terminal of the TFT-K in the driving circuit 115(n−1) is connected to the gate line 13G(n). The gate terminal of the TFT-B in the driving circuit 115(n+1) is connected to the netA(n), the gate terminal of the TFT-B in the driving circuit 115(n) is connected to the netA(n−1), the gate terminal of the TFT-B in the driving circuit 115(n−1) is connected to a netA(n−2), which is not illustrated in the drawing.

Further, in FIG. 28D, the respective drain terminals of the TFTs-F in the driving circuit 115(n−1) and driving circuit 115(n+1) are connected to the line 15L to which the clock signal CKb is supplied, as illustrated in FIG. 28E. The respective drain terminals of the TFTs-F in the driving circuit 115(n) are connected to the line 15L to which the clock signal CKa is supplied, as illustrated in FIG. 28E.

### (Exemplary Operation)

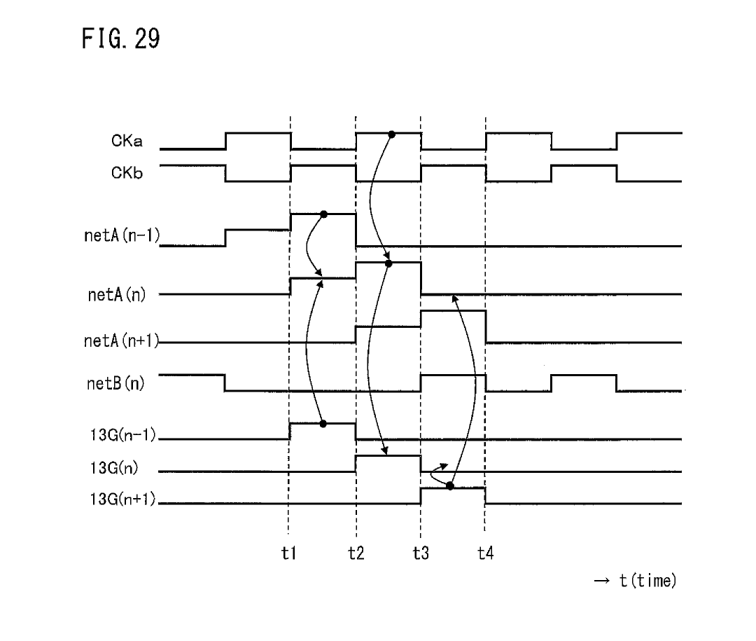

Next, the following describes operations of the driving circuit 115 in the present modification example. FIG. 29 is a timing chart illustrating timings of operations by the driving circuit 115 for driving the gate line 13G.

From a time t1 to a time t2, the potential of the netA(n−1) in the driving circuit 115(n−1) is supplied to the gate terminal of the TFT-B, and the potential of the gate line 13G(n−1) is supplied to the drain terminal of the TFT-B. After precharge, the potential of the netA(n−1) is boosted up through the capacitor Cbst, and from the time t1 to the time t2, the netA(n−1) is charged (main charge) to have a potential higher than the potential of (the H level (VDD) plus the threshold voltage of the TFT-F).

During a period from the time t1 to the time t2, the H-level potential of the clock signal CKb is supplied to the gate terminal and the drain terminal of the TFT-G, and the H-level potential of the gate line 13G(n−1) is supplied to the gate terminal of the TFT-J. The netB(n) therefore maintains the L-level potential through the TFT-J, and the TFT-C is turned OFF.

As a result, during the period from the time t1 to the time t2, the voltage precharged to the netA(n) does not fall by the threshold voltage of the TFT-B, and hence, the netA(n) is precharged to the H level (VDD). This causes the TFTs-F to be turned ON, but since from the time t1 to the time t2, the potential of the clock signal CKa is at the L level, the L-level potential is output to the gate line 13G(n).

Next, at the time t2, when the potential of the clock signal CKa rises to the H level, the potential of the precharged netA(n) is boosted up through the capacitor Cbst in the driving circuit 115(n), whereby the netA(n) is charged (main charge) so as to has the potential of (the H level (VDD) plus the threshold voltage of the TFT-F). Further, here, the potential of the netB(n) is maintained at the L level through the TFT-H, and the TFT-C is in the OFF state. As a result, during a period from the time t2 to the time t3, the H-level potential (VDD) of the clock signal CKa is output to the gate line 13G(n) through the TFTs-F, and the gate line 13G(n) is switched to the selected state.

Next, at a time t3, when the gate line 13G(n+1) is switched to the selected state, H-level potential of the gate line 13G(n+1) is supplied to the gate terminals of the TFT-K and the TFT-L in the driving circuit 115(n). This causes the potential of the netA(n) to be pulled down to the L level through the TFT-K, and causes the potential of the gate line 13G(n) to be pulled down to the L level through the TFT-L.

After a time t4, the potential of the gate line 13G(n+1) falls to the L level, and the TFT-K and the TFT-L are turned OFF. But at a timing when the potential of the clock signal CKb rises to the H level, the netB(n) is charged so as to have the potential of (the VDD minus the threshold voltage of the TFT-G) through the TFT-G. This causes the TFT-C to be turned ON, and the potential of the netA(n) is maintained at the L level (VSS) through the TFT-C.

In the present modification example, the driving circuit 115 is caused to operate by using the two-phase clock signals, and this makes it possible to reduce the number of the lines 15L for supplying the clock signals, as compared with Embodiment 1, thereby reducing the electric power consumption for the supply of the clock signals.

(2) In the foregoing description of Embodiment 5, an example is described in which four row selection signals are used, but alternatively, the configuration may be such that two row selection signals are used for driving any gate lines 13G. In this case, for example, the row selection signal ENA is input to the drain terminals of the TFTs-P of the driving circuit 114(n) and the driving circuit 114(n−1). Further, the row selection signal ENB is input to the drain terminals of the TFTs-P in the driving circuit 114(n+1) and the driving circuit 114(n+2) in pair, and the drain terminals of the TFTs-P in the driving circuit 114(n−2) and the driving circuit 114(n−3) driving the gate line 13G(n−3) in pair. In other words, the same row selection signal is input to two driving circuits 114 provided with respect to two adjacent gate lines.

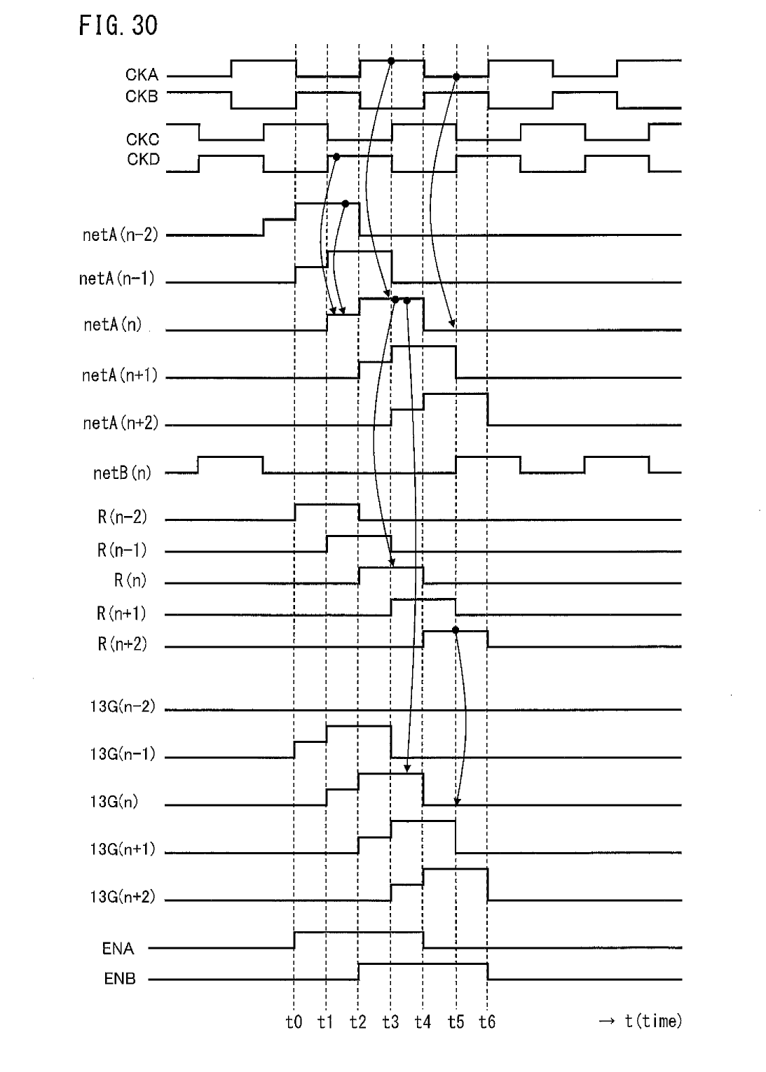

FIG. 30 is a timing chart illustrating timings of driving the gate lines 13G in the present modification example. The display control circuit 4 (see FIG. 3) outputs the H-level row selection signal ENA when driving the gate lines 13G(n−1), 13G(n), and outputs the H-level row selection signal ENB when driving the gate lines 13G(n−2), 13G(n+1), 13G(n+2).

As illustrated in FIG. 30, during a period from a time tO to a time t4, the row selection signal ENA has a potential at the H level, and during a period from a time t2 to a time t6, the row selection signal ENB has a potential at the H level. In other words, the row selection signal ENA has a potential at the H level during a period for the precharge and the main charge of the netA(n−1) and the netA(n), and the row selection signal ENB has a potential at the H level during a period for the precharge and the main charge of the netA(n+1) and the netA(n+2).

As a result, the H-level potential of the row selection signal ENA is supplied to the gate line 13G(n−1) through the TFT-P in the driving circuit 114(n−1) during a period from the time to to a time t3, and is supplied to the gate line 13G(n) through the TFT-P in the driving circuit 114(n) from a time t1 to the time t4. Further, the H-level potential of the row selection signal ENB is supplied to the gate line 13G(n+1) through the TFT-P in the driving circuit 114(n+1) from the time t2 to the time t5, and is supplied to the gate line 13G(n+2) through the TFT-P in the driving circuit 114(n+2) from the time t3 to the time t6.

It should be noted that, from the time tO to the time t2, since the row selection signal ENB has a potential at the L level, the L-level potential is supplied to the gate line 13G(n−2) through the TFT-P in the driving circuit 114(n−2), whereby the gate line 13G(n−2) is maintained in the non-selected state.

In the present modification example, the gate line driving control can be performed in units of two gate lines by using two row selection signal. This makes it possible to reduce the number of the lines 15L for supplying row selection signals, as compared with Embodiment 5, thereby reducing the electric power consumption for supply of row selection signals.

(3) In the foregoing description of Embodiments 1 to 5, examples are described in which the driving circuits of the gate drivers are provided in the display region 201, but alternatively, the gate drivers may be provided outside the display region 201.

(4) Embodiment 2 and /or Embodiment 3 may be applied to Embodiment 1 or the application example of Embodiment 1 described above. In other words, the potential of the netA(n+2) may be supplied to the gate terminal of the TFT-K in the driving circuit 11 or 110, and a clock signal may be supplied to the drain terminal thereof. Further, the potential of the netA(n+2) may be supplied to the gate terminal of the TFT-L in the driving circuit 11 or 110, and a clock signal may be input to the drain terminal thereof.

1. A shift register circuit that switches each of a plurality of gate lines provided on an active matrix substrate to a selected state or a non-selected state, the shift register circuit comprising:
a plurality of driving circuits that are connected to the respective gate lines and switch the gate lines to a selected state or a non-selected state,
wherein each of the driving circuits includes:
an output unit that includes a switching element that is connected to one of the gate lines, and outputs a selection voltage for switching the one gate line to a selected state;
a precharge unit that includes a switching element that outputs a control voltage for causing the switching element in the output unit to operate;
a boosting unit that includes a capacitor and a switching element that charges the capacitor, and boosts up a gate voltage of the switching element in the output unit through the capacitor;
a gate voltage discharge unit that includes a switching element that pulls down the gate voltage during a non-selection period while the one gate line is switched to the non-selected state;
a gate line discharge unit that includes a switching element that outputs a non-selection voltage to the one gate line during the non-selection period while the one gate line is not selected; and
an internal line to which the gate terminal of the switching element in the output unit, the precharge unit, the gate voltage discharge unit, and the boosting unit are connected,
wherein a gate terminal of at least one switching element among the switching elements in the precharge unit, the gate voltage discharge unit, and the gate line discharge unit is connected to the internal line of another one of the driving circuits
wherein, regarding the switching element in the precharge unit, a gate terminal thereof is connected to the internal line in the another driving circuit, a source terminal thereof is connected to the internal line in the present driving circuit, and a drain terminal thereof is supplied with a control signal having a potential switched every predetermined period between a potential corresponding to the selected state and a potential corresponding to the non-selected state.

2-3. (canceled)

4. The shift register circuit according to claim 1,
wherein, regarding the switching element in the gate voltage discharge unit, a gate terminal thereof is connected to the internal line in the another driving circuit, a source terminal thereof is connected to the internal line in the present driving circuit, and a drain terminal thereof is supplied with a control signal having a potential switched every predetermined period between a potential corresponding to the selected state and a potential corresponding to the non-selected state.

5. The shift register circuit according to claim 1,
wherein, regarding the switching element in the gate line discharge unit, a gate terminal thereof is connected to the internal line in the another driving circuit, a source terminal thereof is connected to the one gate line, and a drain terminal thereof is supplied with a control signal having a potential switched every predetermined period between a potential corresponding to the selected state and a potential corresponding to the non-selected state.

6. The shift register circuit according to claim 1,
wherein, regarding the switching element in the output unit, a source terminal thereof is connected to the one gate line, and a drain terminal thereof is supplied with a direct current voltage signal having a potential corresponding to the selected state.

7. The shift register circuit according to claim 1,
wherein, regarding the switching element in the output unit, a source terminal thereof is connected to the one gate line, and a drain terminal thereof is supplied with an instruction signal having a potential corresponding to either one of the selected state and the non-selected state.

8. The shift register circuit according to claim 1,
wherein a plurality of source lines crossing each of the gate lines are provided on the active matrix substrate, and
the driving circuits are provided in a display region defined by the gate lines and the source lines.

9. A display device comprising:
an active matrix substrate including the shift register circuit according to claim 1;
a counter substrate including color filters; and
a liquid crystal layer interposed between the active matrix substrate and the counter substrate.
